(19) United States
(12) Patent Application Publication
(10) Pub. No.: US 2015/0287706 A1
(43) Pub. Date: Oct. 8, 2015

(54) SEMICONDUCTOR DEVICE AND METHOD FOR MANUFACTURING THE SAME

(71) Applicant: Mitsunari SUKEKAWA, (US)

(72) Inventor: Mitsunari Sukekawa, Tokyo (JP)

(21) Appl. No.: 14/438,118

(22) PCT Filed: Sep. 13, 2013
(86) PCT No.: PCT/JP2013/074878

§ 371 Date: Apr. 23, 2015

(30) Foreign Application Priority Data
Oct. 24, 2012 (JP) 2012-234556
Feb. 25, 2013 (JP) 2013-035026
Sep. 4, 2013 (JP) 2013-183019

(51) Int. Cl. H01L 25/18; H01L 27/108; H01L 23/532; H01L 23/528; H01L 27/088; H01L 23/48; H01L 25/065; H01L 23/544

(52) U.S. Cl. CPC H01L 25/18; H01L 25/0657; H01L 27/10805; H01L 23/544; H01L 23/528; H01L 27/088; H01L 23/481; H01L 23/53228; H01L 2225/06541; H01L 2223/54426

(57) ABSTRACT

A semiconductor device comprising: a first semiconductor chip provided with a first function, including a memory element but not including a peripheral circuit; first connection terminals provided in the first semiconductor chip; a second semiconductor chip provided with a second function, including a peripheral circuit but not including a memory element; and second connection terminals provided in the second semiconductor chip, wherein the first semiconductor chip and the second semiconductor chip are stacked on one another by causing the first connection terminals and the second connection terminals to come into contact with one another.

### TECHNICAL FIELD

The present invention relates to a semiconductor device and a method for manufacturing the same.

### BACKGROUND ART

Generally, a DRAM (Dynamic Random Access Memory) comprises a memory cell region (generally formed as an NMOS) having a capacitor structure, and a peripheral circuit region comprising CMOS circuits. With the progress of miniaturization, differences have arisen in the manufacturing processes for the respective regions, and thus if the regions are manufactured on the same wafer, there are sometimes problems in that semiconductor process constraints cause a deterioration in their respective performances, and the manufacturing cost also increases.

Examples of the related art are described in JP2011-228484 (patent literature 1), JP2006-319243 (patent literature 2) and JP2008-16720 (patent literature 3).

Patent literature 1 discloses stacking a DRAM core chip and an interface chip on one another, and electrically connecting them using through-electrodes (see paragraphs [0006] and [0044] and FIG. 12). The technique disclosed here is known as Chip On Chip (COC), with the DRAM chip and the interface chip stacked on one another. In addition to the memory cell portion, the DRAM chip must also be equipped internally with CMOS sense amplifier circuits and input and output circuit interface circuits.

Patent literature 2 discloses the provision of through-electrodes in stacked memory core chips (see paragraph [0022] and FIG. 1). The technique disclosed here is a COC technique with which, in addition to the memory cell portion, the memory core chips must also be equipped internally with CMOS sense amplifier circuits and input and output circuit interface circuits.

Patent literature 3 discloses a step in which a semiconductor wafer in which a plurality of chips are formed is diced into a plurality of chip groups, and a step in which module sets are formed by stacking the chip groups on one another, and said patent literature 3 also discloses that the chips are preferably memory chips, and that through-electrodes are provided in such a way as to penetrate through the chips (see paragraph [0020]). The technique disclosed here is a COC technique, or a technique known as Wide I/O in which DRAMs are stacked on one another, and in addition to the memory cell portion, the memory chips or the DRAMs must also be equipped internally with CMOS sense amplifier circuits and input and output circuit interface circuits.

### CITATION LIST

### Patent Literature

Patent literature 1: 2011-228484 A
Patent literature 2: 2006-319243 A
Patent literature 3: 2008-16720 A

### SUMMARY OF THE INVENTION

### Technical Problem

The present invention resolves the problems in the abovementioned prior art, and provides a semiconductor device, and a method for manufacturing the same, with which it is possible to prevent a deterioration in performance arising as a result of semiconductor process constraints in a region having a memory function and a region having a peripheral circuit function, and with which it is possible to suppress an increase in the manufacturing cost.

### Solution to Problems

A semiconductor device according to one mode of embodiment of the present invention is characterized in that it comprises:

a first semiconductor chip provided with a first function, including a memory element but not including a peripheral circuit;
first connection terminals provided in the first semiconductor chip;
a second semiconductor chip provided with a second function, including a peripheral circuit but not including a memory element; and
second connection terminals provided in the second semiconductor chip, wherein the first semiconductor chip and the second semiconductor chip are stacked on one another by causing the first connection terminals and the second connection terminals to come into contact with each other.

A semiconductor device according to another mode of embodiment of the present invention is characterized in that it comprises:

a first semiconductor chip having transistors of only a first conductor type;
first connection terminals provided in the first semiconductor chip;
a second semiconductor chip having transistors of the first conductor type and transistors of a second conductor type; and
second connection terminals provided in the second semiconductor chip, wherein the first semiconductor chip and the second semiconductor chip are stacked on one another by causing the first connection terminals and the second connection terminals to come into contact with each other.

Further, a method of manufacturing a semiconductor device according to one mode of embodiment of the present invention is characterized in that it comprises:

forming, in a first manufacturing process, a first semiconductor chip provided with a first function, including a memory element but not including a peripheral circuit;
forming, in a second manufacturing process, a second semiconductor chip provided with a second function, including a peripheral circuit but not including a memory element; and
stacking the first semiconductor chip and the second semiconductor chip on one another by laminating the obverse surfaces of the first semiconductor chip and the second semiconductor chip to each other.

### Advantageous Effect of the Invention

According to the present invention it is possible to prevent a deterioration in performance arising as a result of semiconductor process constraints in a memory cell region and a peripheral circuit region, and to suppress an increase in the manufacturing cost.

### BRIEF DESCRIPTION OF THE DRAWINGS

FIG. 1 is a drawing illustrating the structure of a semiconductor device (DRAM) according to a mode of embodiment of the present invention.

FIG. 2 is a drawing illustrating the structure of a memory semiconductor substrate, where (a) is an oblique view of the memory semiconductor substrate, (b) is an enlarged view of a shot in the memory semiconductor substrate, (c) is a region layout view of a semiconductor memory chip, and (d) is a plan view of the semiconductor memory chip.

FIG. 3 is a drawing illustrating the structure of the memory semiconductor substrate, where (a) is a region layout view of a memory cell bank, (b) is a plan view of the memory cell bank, and (c) is a plan view of the memory cell bank, in which connection terminals are arranged in a staggered lattice formation.

FIG. 4 is a drawing illustrating the structure of the memory semiconductor substrate, where (a) is an enlarged view of the portion A in FIGS. 3 (b), and (b) is a cross-sectional view along A-B in FIG. 4 (a).

FIG. 5 is a drawing illustrating the structure of a CMOS semiconductor substrate, where (a) is an oblique view of the CMOS semiconductor substrate, (b) is an enlarged view of a shot in the CMOS semiconductor substrate, (c) is a region layout view of a semiconductor CMOS chip, and (d) is a plan view of the semiconductor CMOS chip.

FIG. 6 is a drawing illustrating the structure of the CMOS semiconductor substrate, where (a) is a region layout view of a CMOS bank, (b) is a plan view of the CMOS bank, and (c) is a plan view of the CMOS bank, in which connection terminals are arranged in a staggered lattice formation.

FIG. 7 is a drawing illustrating the structure of the CMOS semiconductor substrate, where (a) is an enlarged view of the portion B in FIGS. 6 (a), and (b) is an enlarged view of the portion C in FIG. 6 (b).

FIG. 8 is a drawing illustrating the structures of a semiconductor memory chip and a semiconductor CMOS chip, where (a) is a cross-sectional view of the semiconductor memory chip, and (b) is a cross-sectional view of the semiconductor CMOS chip.

FIG. 9 is a drawing used to describe a method of manufacturing a semiconductor device according to a mode of embodiment of the present invention, where (a) is a process block diagram of the manufacturing method, and (b) is a drawing illustrating changes in a cross-section during the manufacturing process.

FIG. 10 is a drawing illustrating the structure of a semiconductor device in the related art, where (a) is a block connection diagram of circuit regions in a DRAM semiconductor device in the related art, and (b) is a cross-sectional view of the DRAM semiconductor device in the related art.

FIG. 11 is a drawing illustrating the structure of a second mode of embodiment of the present invention, where (a) is an enlarged view of the portion A in FIGS. 3 (b), and (b) is a cross-sectional view along B-B in FIG. 11 (a).

FIG. 12 is a drawing illustrating the configuration of a CMOS semiconductor substrate, where (a) is an oblique view, (b) is an enlarged view of shot 150, (c) is a region layout view of a semiconductor CMOS chip, and (d) is a plan view of the semiconductor CMOS chip.

FIG. 13 is a drawing illustrating the structure of a CMOS bank, where (a) is a region layout view of the CMOS bank, and (b) is a plan view of the CMOS bank.

FIG. 14 is a schematic diagram illustrating three-dimensionally a portion in the vicinity of the cross-section C-C in FIG. 13 (b).

FIG. 15 is a drawing illustrating the wiring line pattern in a first wiring line layer in a corner portion of a peripheral circuit bank.

FIG. 16 is a drawing illustrating the wiring line pattern in a second wiring line layer in the corner portion of the peripheral circuit bank.

FIG. 17 is a drawing illustrating the wiring line pattern in a third wiring line layer in the corner portion of the peripheral circuit bank.

FIG. 18 is a drawing illustrating the wiring line pattern in a connection terminal layer in the corner portion of the peripheral circuit bank.

FIG. 19 (a) is a region layout view of a CMOS bank, and (b) is a plan view of the CMOS bank.

FIG. 20 is a schematic diagram illustrating three-dimensionally a portion in the vicinity of the cross-section C-C in FIG. 19 (b).

FIG. 21 is a drawing illustrating the wiring line pattern in a first wiring line layer in a corner portion of a peripheral circuit bank.

FIG. 22 is a drawing illustrating the wiring line pattern in a second wiring line layer in the corner portion of the peripheral circuit bank.

FIG. 23 is a drawing illustrating the wiring line pattern in a third wiring line layer in the corner portion of the peripheral circuit bank.

FIG. 24 is a drawing illustrating the wiring line pattern in a connection terminal layer in the corner portion of the peripheral circuit bank.

FIG. 25 is a plan view of a memory cell bank according to a fourth mode of embodiment of the present invention.

FIG. 26 (a) is an enlarged view of the portion A in FIG. 25, and (b) is a cross-sectional view along B-B in FIG. 26 (a).

FIG. 27 is a drawing used to describe a method of manufacturing a memory semiconductor substrate according to the fourth mode of embodiment of the present invention, where (a) is a plan view corresponding to FIGS. 26 (a), and (b) is a cross-sectional view corresponding to FIG. 26 (b).

FIG. 28 is a drawing used to describe the method of manufacturing the memory semiconductor substrate according to the fourth mode of embodiment of the present invention, where (a) is a plan view corresponding to FIGS. 26 (a), and (b) is a cross-sectional view corresponding to FIG. 26 (b).

FIG. 29 is a drawing used to describe the method of manufacturing the memory semiconductor substrate according to the fourth mode of embodiment of the present invention, where (a) is a plan view corresponding to FIGS. 26 (a), and (b) is a cross-sectional view corresponding to FIG. 26 (b).

FIG. 30 is a drawing used to describe the method of manufacturing the memory semiconductor substrate according to the fourth mode of embodiment of the present invention, where (a) is a plan view corresponding to FIGS. 26 (a), and (b) is a cross-sectional view corresponding to FIG. 26 (b).

FIG. 31 is a drawing illustrating the structure of a 4F2-structure memory cell semiconductor substrate in a fifth mode of embodiment of the present invention, where (a) is a plan view illustrating the arrangement of the main parts of the memory cell semiconductor substrate, (b) is a cross-sectional view along A-A in (a), and (c) is a cross-sectional view along B-B in (a).

FIG. 32 is a drawing used to describe the method of manufacturing a memory semiconductor substrate in the fifth mode of embodiment of the present invention.

FIG. 33 is a drawing used to describe the method of manufacturing the memory semiconductor substrate in the fifth mode of embodiment of the present invention.

FIG. 34 is a drawing used to describe the method of manufacturing the memory semiconductor substrate in the fifth mode of embodiment of the present invention.

FIG. 35 is a drawing used to describe the method of manufacturing the memory semiconductor substrate in the fifth mode of embodiment of the present invention.

FIG. 36 is a drawing used to describe the method of manufacturing the memory semiconductor substrate in the fifth mode of embodiment of the present invention.

FIG. 37 is a drawing used to describe the method of manufacturing the memory semiconductor substrate in the fifth mode of embodiment of the present invention.

FIG. 38 is a drawing used to describe the method of manufacturing the memory semiconductor substrate in the fifth mode of embodiment of the present invention.

FIG. 39 is a drawing used to describe the method of manufacturing the memory semiconductor substrate in the fifth mode of embodiment of the present invention.

FIG. 40 is a drawing used to describe the method of manufacturing the memory semiconductor substrate in the fifth mode of embodiment of the present invention.

FIG. 41 is a drawing used to describe the method of manufacturing the memory semiconductor substrate in the fifth mode of embodiment of the present invention.

FIG. 42 is a drawing used to describe the method of manufacturing the memory semiconductor substrate in the fifth mode of embodiment of the present invention.

FIG. 43 is a drawing used to describe the method of manufacturing the memory semiconductor substrate in the fifth mode of embodiment of the present invention.

FIG. 44 is a drawing used to describe the method of manufacturing the memory semiconductor substrate in the fifth mode of embodiment of the present invention.

FIG. 45 is a drawing used to describe the method of manufacturing the memory semiconductor substrate in the fifth mode of embodiment of the present invention.

FIG. 46 is a plan view of a memory semiconductor substrate in a sixth mode of embodiment of the present invention.

FIG. 47 is a cross-sectional view in which a cross-section along A-A in FIG. 46 is projected onto a vertical plane extending in a first direction X.

FIG. 48 is a cross-sectional view in which a cross-section along B-B in FIG. 46 is projected onto a vertical plane extending in a second direction Y.

FIG. 49 is a drawing used to describe a method of manufacturing the memory semiconductor substrate in the sixth mode of embodiment of the present invention.

FIG. 50 is a drawing used to describe the method of manufacturing the memory semiconductor substrate in the sixth mode of embodiment of the present invention.

FIG. 51 is a drawing used to describe the method of manufacturing the memory semiconductor substrate in the sixth mode of embodiment of the present invention.

FIG. 52 is a drawing used to describe the method of manufacturing the memory semiconductor substrate in the sixth mode of embodiment of the present invention.

FIG. 53 is a drawing used to describe the method of manufacturing the memory semiconductor substrate in the sixth mode of embodiment of the present invention.

FIG. 54 is a drawing used to describe the method of manufacturing the memory semiconductor substrate in the sixth mode of embodiment of the present invention.

FIG. 55 is a plan view of a memory semiconductor substrate in a seventh mode of embodiment of the present invention.

FIG. 56 is a cross-sectional view in which a cross-section along C-C in FIG. 55 is projected onto a vertical plane extending in the first direction X.

FIG. 57 is a cross-sectional view in which a cross-section along D-D in FIG. 55 is projected onto a vertical plane extending in the second direction Y.

FIG. 58 is a plan view of the memory semiconductor substrate in the seventh mode of embodiment of the present invention.

FIG. 59 is a cross-sectional view in which a cross-section along C-C in FIG. 58 is projected onto a vertical plane extending in the first direction X.

FIG. 60 is a cross-sectional view in which a cross-section along D-D in FIG. 58 is projected onto a vertical plane extending in the first direction X.

### DESCRIPTION OF EMBODIMENTS

### Related Art

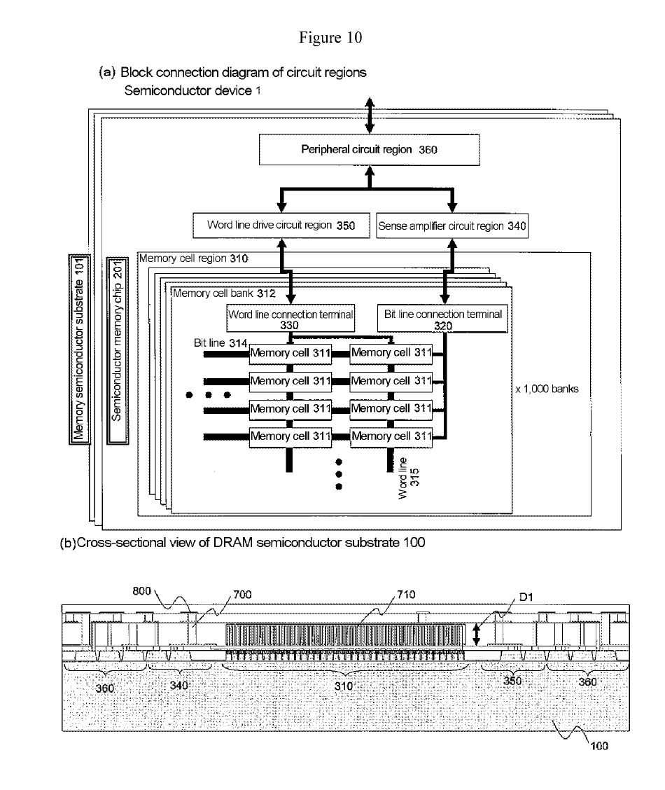

A semiconductor device (DRAM) according to the related art will first be described with reference to FIG. 10, in order to clarify the characteristics of the present invention. FIG. 10 is a drawing illustrating the structure of a semiconductor device according to the related art.

FIG. 10 (a) is a block connection diagram of circuit regions in a DRAM semiconductor device 1 in the related art.

Peripheral circuit regions (referred to collectively as a peripheral circuit region 360) excluding a sense amplifier circuit region 340 and a word line drive circuit region 350 are disposed abutting and electrically connecting the sense amplifier region 340 and the word line drive circuit region 350. A portion of the peripheral circuit region 360 exchanges signals with the outside.

FIG. 10 (b) is a cross-sectional view of the DRAM semiconductor device 1 in the related art.

A memory cell region 310, the sense amplifier circuit region 340, the word line drive circuit region 350 and the peripheral circuit regions 360 are disposed adjacent to one another in a planar fashion, but because the memory cell region 310 contains capacitors 710, which are storage elements, a step D1 is generated between the sense amplifier circuit region 340, the word line drive circuit region 350 and the peripheral circuit regions 360.

With the progress of miniaturization, differences have arisen in the manufacturing processes for the respective regions, and thus if the regions are manufactured on the same wafer, there are problems in that semiconductor process constraints cause a deterioration in their respective performances, and the manufacturing cost also increases. Here, the memory cell region 310, the sense amplifier circuit region 340, the word line drive circuit region 350 and the peripheral circuit regions 360 are referred to collectively as circuit regions 300.

The present invention resolves the problems in the abovementioned related art, and provides a semiconductor device, and a method for manufacturing the same, with which it is possible to prevent a deterioration in performance arising as a result of semiconductor process constraints in a memory cell region and a peripheral circuit region, and with which it is possible to suppress an increase in the manufacturing cost.

### First Mode of Embodiment of the Present Invention

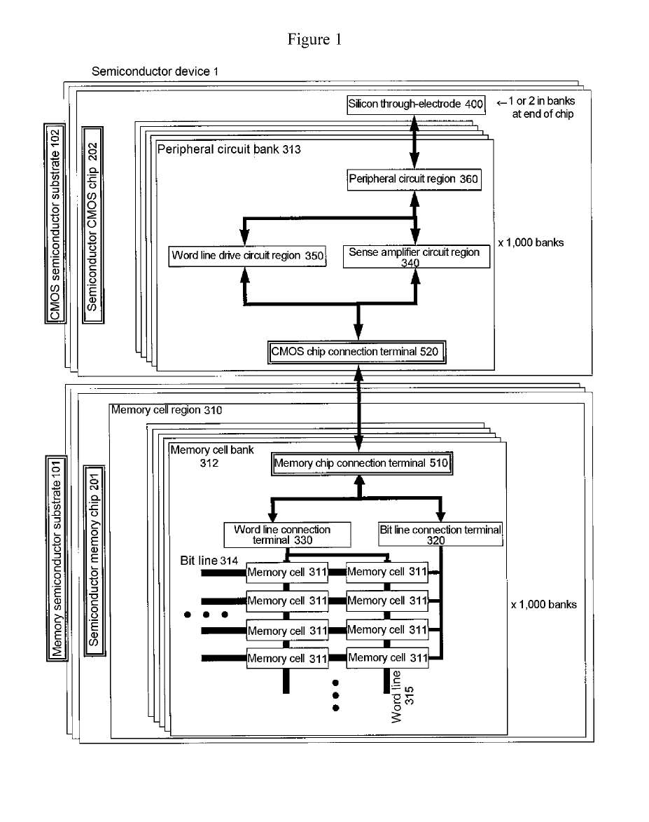

A first mode of embodiment of the present invention will now be described in detail with reference to the drawings. FIG. 1 is a drawing illustrating the structure of a semiconductor device (DRAM) 1 according to the first mode of embodiment of the present invention.

The structure of the semiconductor device 1 according to the first embodiment of the present invention will be described with reference to FIG. 1.

The semiconductor device 1 according to the first mode of embodiment of the present invention comprises a memory semiconductor substrate 101 and a CMOS semiconductor substrate 102.

The memory semiconductor substrate 101 comprises a plurality of semiconductor memory chips 201 disposed in a planar manner, the semiconductor memory chips 201 being memory cell regions 310 having a plurality (approximately 1,000, for example) of memory cell banks 312 comprising: a plurality of memory cells 311 disposed lengthwise and crosswise; bit lines 314 and word lines 315 intersecting one another and connected to the plurality of memory cells 311; bit line connection terminals 320 and word line connection terminals 330 electrically connected to the bit lines 314 and the word lines 315; and memory chip connection terminals 510 connected in a one-to-one relationship to the bit line connection terminals 320 and the word line connection terminals 330 by way of wiring lines and contacts, discussed hereinafter. The semiconductor memory chips 201 comprise memory elements.

Meanwhile, the CMOS semiconductor substrate 102 comprises a plurality of semiconductor CMOS chips 202 disposed in a planar manner, the semiconductor CMOS chips 202 having a plurality (approximately 1,000, for example) of peripheral circuit banks 313 comprising: a peripheral circuit region 360; a sense amplifier circuit region 340 and a word line drive circuit region 350 which are electrically connected to the peripheral circuit region 360; a CMOS chip connection terminal 520 connected to the sense amplifier circuit region 340 and the word line drive circuit region 350 by way of wiring lines and contacts, discussed hereinafter; and peripheral circuit banks 313 having silicon through-electrodes 400 that are electrically connected to the peripheral circuit region 360 and that exchange signals with the outside, being peripheral circuit banks 313 that are in a peripheral portion of the semiconductor CMOS chip 202. The semiconductor CMOS chips 202 comprise peripheral circuits, where the circuits in the sense amplifier circuit region 340, the word line drive circuit region 350 and the peripheral circuit region 360 are referred to collectively as peripheral circuits.

With such a configuration, the obverse surfaces of the memory semiconductor substrate 101 and the CMOS semiconductor substrate 102 are pressure bonded in such a way that the memory chip connection terminals 510 and the CMOS chip connection terminals 520 are electrically connected in a one-to-one relationship, and after the CMOS semiconductor substrate 102 has been ground until the end portions of the silicon through-electrodes 400 appear at the surface, the memory semiconductor substrate 101 and the CMOS semiconductor substrate 102 are separated into blocks (hereinafter referred to as semiconductor chips 200) comprising a semiconductor memory chip 201 and a semiconductor CMOS chip 202. The semiconductor chip 200 contains all the circuit regions 300 in the semiconductor device 1 in the abovementioned related art and realizes the same functions. It should be noted that the memory chip connection terminals 510 and the CMOS chip connection terminals 520 preferably each contain copper.

Here, the memory cell regions 310 are formed on the memory semiconductor substrate 101, and the peripheral circuit region 360, the sense amplifier circuit region 340 and the word line drive circuit region 350 are formed on the CMOS semiconductor substrate 102. Said regions can thus be manufactured using different manufacturing processes, and without generating a step, and therefore semiconductor process constraints are eliminated, and it is possible to suppress deteriorations in performance and increases in the manufacturing cost.

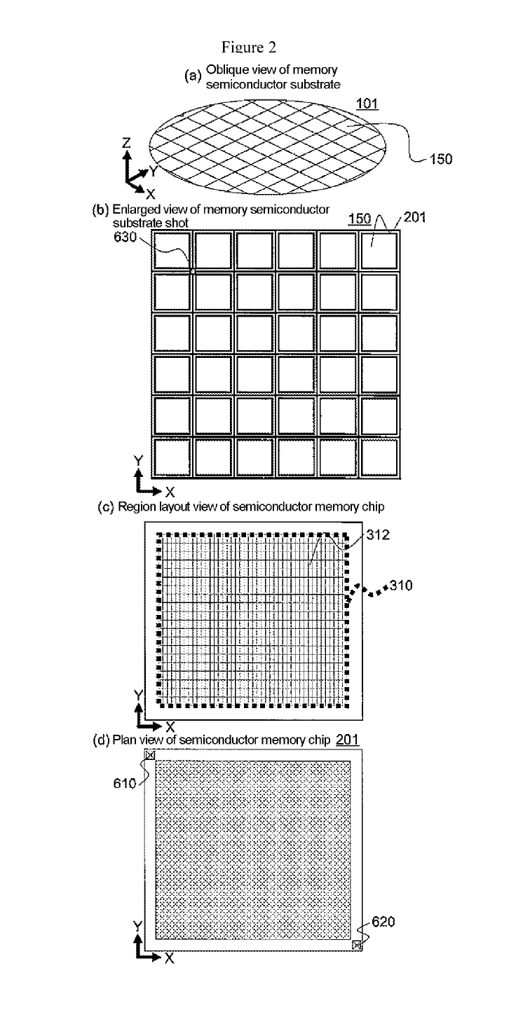

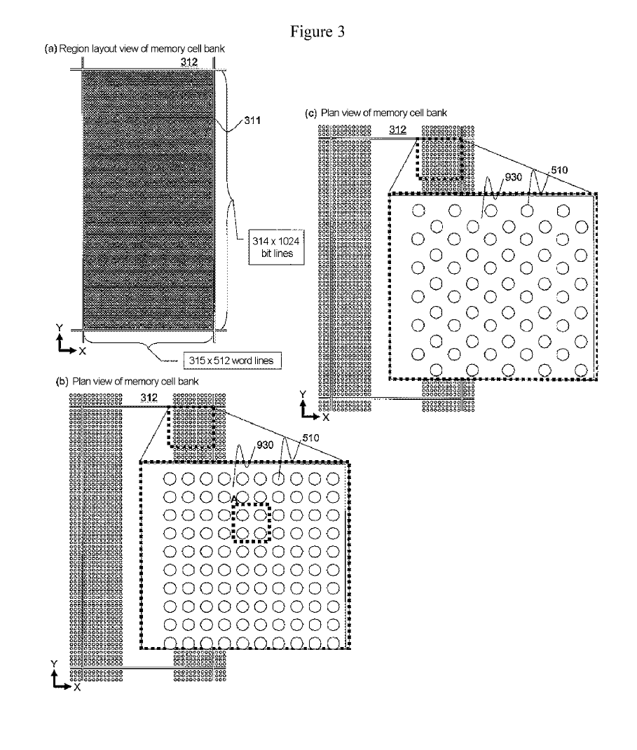

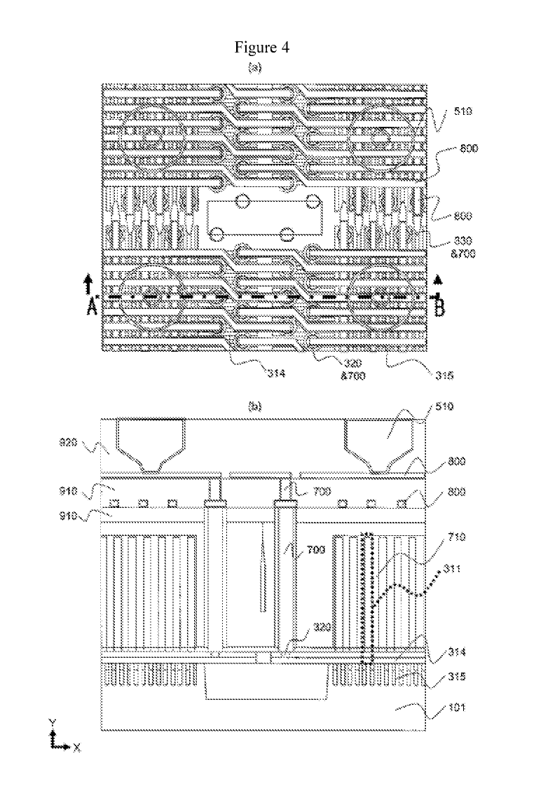

The structure of the memory semiconductor substrate 101 will next be described with reference to FIG. 2, FIG. 3 and FIG. 4. Here, FIG. 2 (a) is an oblique view of the memory semiconductor substrate 101, FIG. 2 (b) is an enlarged view of a shot 150 in the memory semiconductor substrate 101, FIG. 2 (c) is a region layout view of the semiconductor memory chip 201, and FIG. 2 (d) is a plan view of the semiconductor memory chip 201. Further, FIG. 3 (a) is a region layout view of the memory cell bank 312, FIG. 3 (b) is a plan view of the memory cell bank 312, and FIG. 3 (c) is a plan view of the memory cell bank 312, in which connection terminals are arranged in a staggered lattice formation. Further, FIG. 4 (a) is an enlarged view of the portion A in FIG. 3 (b), and FIG. 4 (b) is a cross-sectional view along A-B in FIG. 4 (a).

As illustrated in FIG. 2 (a), semiconductor memory chips 201 are disposed in a planar manner in the X-direction and the Y-direction on the obverse surface of the memory semiconductor substrate 101. Here, in connection with light exposure during the semiconductor manufacturing process, a plurality of semiconductor memory chips 201 (20 to 40 chips, for example 36 chips) are managed as a shot 150.

Further, as illustrated in FIG. 2 (b), an IR mark 630 (one or more marks, for example one mark) for grid alignment during lamination of the plurality of semiconductor memory chips 201 and the semiconductor substrate, is disposed on the shot 150. Here, the IR mark 630 is disposed in a position that overlaps an IR mark 630 on the CMOS semiconductor substrate 102, discussed hereinafter, when the obverse surfaces of the memory semiconductor substrate 101 and the CMOS semiconductor substrate 102 are laminated together.

Further, as illustrated in FIG. 2 (c), the memory cell region 310 is disposed over substantially the entire surface of the semiconductor memory chip 201, and the memory cell region 310 comprises a plurality (1,000 for example) of memory cell banks 312.

Further, as illustrated in FIG. 2 (d), the memory cell region 310 is hidden beneath an interlayer insulating film and a protective insulating film which are discussed hereinafter. Alignment marks are arranged on the obverse surface of an outer peripheral portion of the semiconductor memory chip 201, and here, a positioning protuberance (alignment protuberance) 610 and a positioning hole (alignment recess) 620 (referred to collectively as a positioning construction 600) may be provided as the alignment marks.

The positioning construction 600 is disposed in a position such that, when the obverse surfaces of the memory semiconductor substrate 101 and the CMOS semiconductor substrate 102 are laminated together, the positioning protuberance 610 mates with a positioning hole 620 in the CMOS semiconductor substrate 102 discussed hereinafter, and the positioning hole 620 mates with a positioning protuberance 610 on the CMOS semiconductor substrate 102 discussed hereinafter. It should be noted that the positioning construction 600 may be omitted if the accuracy of the grid alignment using the IR marks 630 is high.

Further, as illustrated in FIG. 3 (a), approximately 1,024 bit lines 314 and approximately 512 word lines 315 are disposed over substantially the entire surface of the memory cell bank 312, and one memory cell 311 (which is too small to be illustrated in the drawing) is disposed at each point of intersection between the bit lines 314 and the word lines 315. Further, bit line connection terminals 320 and word line connection terminals 330 (which are not shown in the drawings) are disposed in positions that do not interfere with the memory cells 311, for example at end portions of the bit lines 314 and the word lines 315.

Further, as illustrated in FIG. 3 (b), the memory cells 311, the bit lines 314, the word lines 315, the bit line connection terminals 320 and the word line connection terminals 330 are hidden beneath an interlayer insulating film and a protective insulating film 930, discussed hereinafter. Memory chip connection terminals 510 are disposed on the interlayer insulating film of the memory cell bank 312, and the memory chip connection terminals 510 are connected in a one-to-one relationship to the bit line connection terminals 320 and the word line connection terminals 330 by way of wiring lines and contacts, discussed hereinafter. The memory chip connection terminals 510 are disposed in positions such that, when the obverse surfaces of the memory semiconductor substrate 101 and the CMOS semiconductor substrate 102 are laminated together, the memory chip connection terminals 510 electrically connect in a one-to-one relationship to CMOS connection terminals 520 on the CMOS semiconductor substrate 102, discussed hereinafter.

Here, the memory chip connection terminals 510 may be disposed in a staggered lattice formation, as illustrated in FIG. 3 (c).

Further, as illustrated in FIG. 4 (a), the bit line connection terminals 320 and the word line connection terminals 330 are disposed in positions that do not interfere with the memory cells 311, for example at end portions of the bit lines 314 and the word lines 315. Contacts 700 are disposed connected to the upper surfaces of the bit line connection terminals 320 and the word line connection terminals 330. The memory chip connection terminals 510 are disposed in positions such that they connect to the upper surfaces of contacts 700 via wiring lines 800 and other contacts 700.

Further, as illustrated in FIG. 4 (b), the word lines 315 and the bit lines 314, extending in a direction intersecting the word lines 315, are disposed in such a way as to be embedded in the memory semiconductor substrate 101. One memory cell 311 is disposed at each point of intersection between the bit lines 314 and the word lines 315.

Only capacitors 710 in the upper portions of the memory cells 311 are illustrated in FIG. 4 (b). Further, the bit line connection terminals 320 are disposed in positions that do not interfere with the memory cells 311, for example at the end portions of the bit lines 314. Although not illustrated in the drawings, the word line connection terminals 330 are also disposed in positions that do not interfere with the memory cells 311, for example at the end portions of the word lines 315. The bit line connection terminals 320 and the word line connection terminals 330 (which are not illustrated in the A-B cross-section) are electrically connected in a one-to-one relationship to the memory chip connection terminals 510, via the wiring lines 800 and the contacts 700 which penetrate through a plurality of interlayer insulating films 910.

By increasing the number of layers of wiring lines 800 as necessary it is possible to increase the degree of freedom with which the connection terminals can be arranged, and it is also possible for the connection terminals to be disposed in a staggered lattice formation.

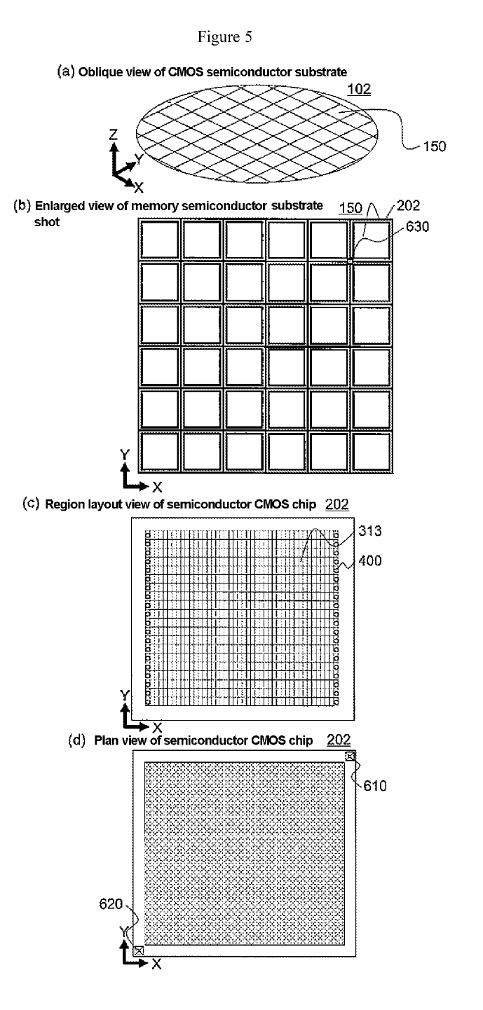

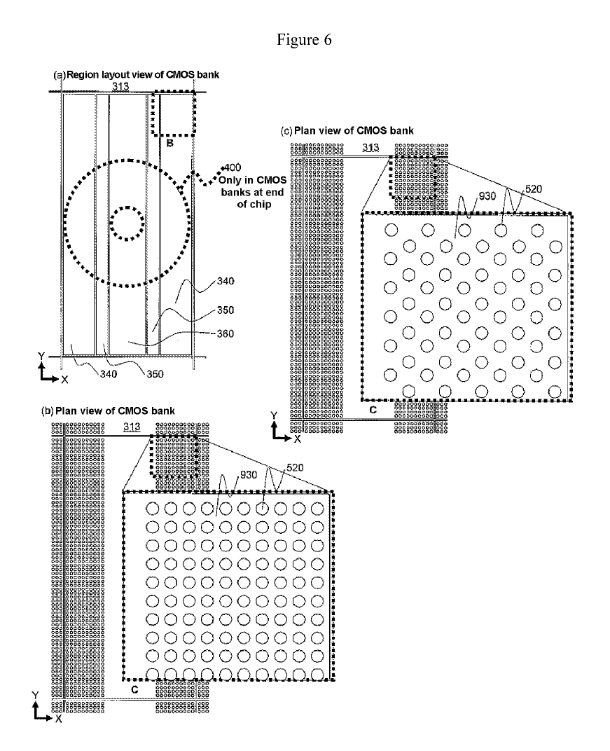

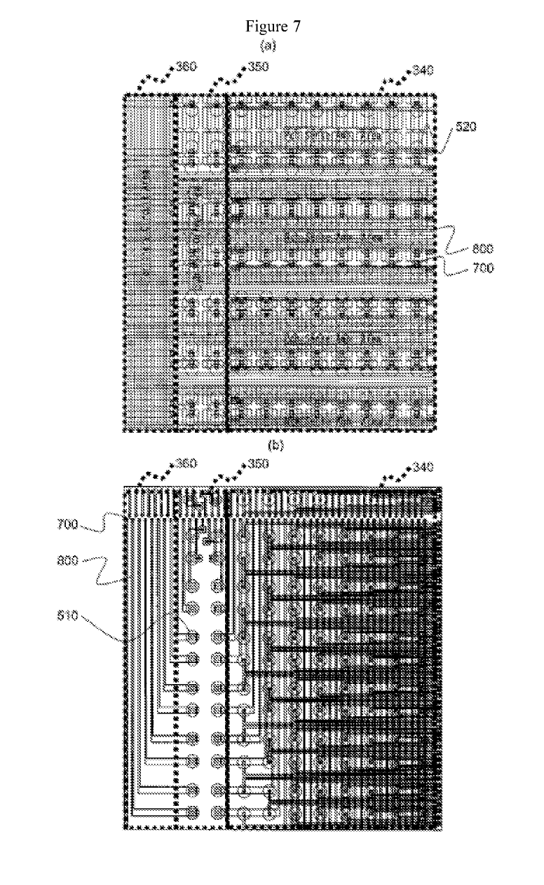

The structure of the CMOS semiconductor substrate 102 will next be described with reference to FIG. 5, FIG. 6 and FIG. 7.

Here, FIG. 5 (a) is an oblique view of the CMOS semiconductor substrate 102, FIG. 5 (b) is an enlarged view of a shot 150 in the CMOS semiconductor substrate 102, FIG. 5 (c) is a region layout view of the semiconductor CMOS chip 202, and FIG. 5 (d) is a plan view of the semiconductor CMOS chip 202. Further, FIG. 6 (a) is a region layout view of the CMOS bank 313, FIG. 6 (b) is a plan view of the CMOS bank 313, and FIG. 6 (c) is a plan view of the CMOS bank 313, in which connection terminals are arranged in a staggered lattice formation. Further, FIG. 7 (a) is an enlarged view of the portion B in FIG. 6 (a), and FIG. 7 (b) is an enlarged view of the portion C in FIG. 6 (b).

As illustrated in FIG. 5 (a), semiconductor CMOS chips 202 are disposed in a planar manner in the X-direction and the Y-direction on the obverse surface of the CMOS semiconductor substrate 102. Here, in connection with light exposure during the semiconductor manufacturing process, a plurality of semiconductor CMOS chips 202 (20 to 40 chips, for example 36 chips) are managed as a shot 150.

Further, as illustrated in FIG. 5 (b), an IR mark 630 (one or more marks, for example one mark) for grid alignment during lamination of the plurality of semiconductor CMOS chips 202 and the semiconductor substrate, is disposed on the shot 150. Here, the IR mark 630 is disposed in a position that overlaps the IR mark 630 on the memory semiconductor substrate 101, discussed hereinabove, when the obverse surfaces of the memory semiconductor substrate 101 and the CMOS semiconductor substrate 102 are laminated together.

Further, as illustrated in FIG. 5 (c), a plurality (1,000 for example) of CMOS banks 313 are disposed over substantially the entire surface of the semiconductor CMOS chip 202. Of the CMOS banks 313, the CMOS banks 313 at the end portions of the semiconductor CMOS chip 202 have one or two silicon through-electrodes 400.

Further, as illustrated in FIG. 5 (d), the CMOS banks 313 are hidden beneath an interlayer insulating film and a protective insulating film which are discussed hereinafter. A positioning protuberance 610 and a positioning hole 620 (referred to collectively as a positioning construction 600) are disposed on the obverse surface of an outer peripheral portion of the semiconductor CMOS chip 202. The positioning construction 600 is disposed in a position such that, when the obverse surfaces of the memory semiconductor substrate 101 and the CMOS semiconductor substrate 102 are laminated together, the positioning protuberance 610 mates with the positioning hole 620 in the memory semiconductor substrate 101 discussed hereinabove, and the positioning hole 620 mates with the positioning protuberance 610 on the memory semiconductor substrate 101 discussed hereinabove. It should be noted that the positioning construction 600 may be omitted if the accuracy of the grid alignment using the IR marks 630 is high.

As illustrated in FIG. 6 (a), a peripheral circuit region 360, sense amplifier circuit regions 340 and word line drive circuit regions 350 are disposed in each CMOS bank 313, and silicon through-electrodes 400 are additionally disposed in the CMOS banks 313 at the end portions of the semiconductor CMOS chip 202.

Signals are exchanged with the outside through the silicon through-electrodes 400. For example, the CMOS chip is disposed on a circuit board, and signals are exchanged via the through-electrodes 400 and terminals on the circuit board.

As illustrated in FIG. 6 (b), the peripheral circuit regions 360, the sense amplifier circuit regions 340, the word line drive circuit regions 350 and the silicon through-electrodes 400 are hidden beneath an interlayer insulating film and a protective insulating film 930, discussed hereinafter. CMOS connection terminals 520 are disposed on the interlayer insulating film of the CMOS bank 313, and are connected to the sense amplifier circuit regions 340 and the word line drive circuit regions 350 by way of wiring lines and contacts, discussed hereinafter. The CMOS connection terminals 520 are disposed in positions such that, when the obverse surfaces of the memory semiconductor substrate 101 and the CMOS semiconductor substrate 102 are laminated together, the CMOS chip connection terminals 520 electrically connect to the memory chip connection terminals 510 on the memory semiconductor substrate 101, discussed hereinabove. Here, the CMOS connection terminal terminals 520 may be disposed in a staggered lattice formation, as illustrated in FIG. 6 (c).

Further, as illustrated in FIG. 7 (a) and FIG. 7 (b), the CMOS connection terminals 520 are connected to the sense amplifier circuit regions 340 and the word line drive circuit regions 350 by way of wiring lines 800 and contacts 700.

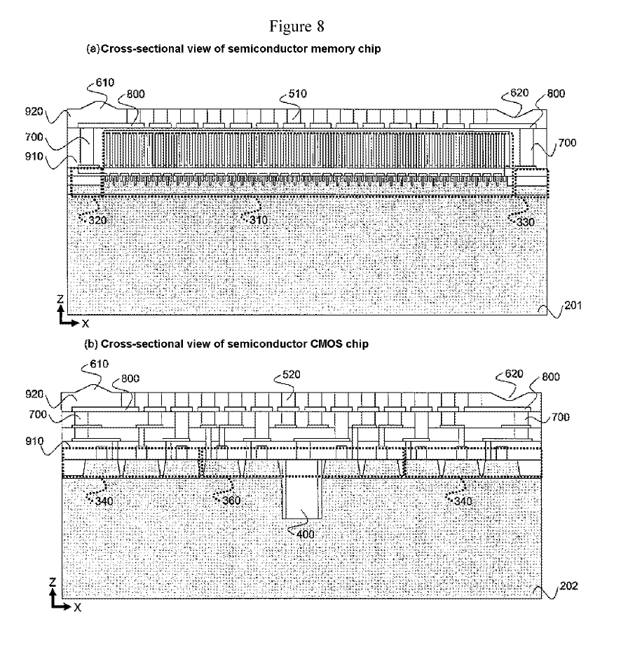

The structure of the semiconductor memory chip 201 and the semiconductor CMOS chip 202 will next be described with reference to FIG. 8. Here, FIG. 8 (a) is a cross-sectional view of the semiconductor memory chip 201, and FIG. 8 (b) is a cross-sectional view of the semiconductor CMOS chip 202.

As illustrated in FIG. 8 (a), the memory cell region 310, and the bit line connection terminals 320 and the word line connection terminals 330 adjacent thereto are disposed on the obverse surface of the semiconductor memory chip 201 (depictions of the detailed structures of these regions are omitted from the drawing).

Interlayer insulating films 910 are disposed in such a way as to cover the memory cell region 310, the bit line connection terminals 320 and the word line connection terminals 330, and the contacts 700 are disposed penetrating through the interlayer insulating films 910 in such a way as to connect electrically to the bit line connection terminals 320 and the word line connection terminals 330. Wiring lines 800 are disposed on and electrically connected to the upper surfaces of the contacts 700, a protective insulating film 920 is disposed in such a way as to cover the interlayer insulating films 910 and the wiring lines 800, and the memory chip connection terminals 510 are disposed penetrating through the protective insulating film 920, electrically connected to the wiring lines 800. Further, the positioning protuberance 610 and the positioning hole 620 are disposed on the obverse surface of the protective insulating film 920.

Further, as illustrated in FIG. 8 (b), the sense amplifier circuit regions 340, the word line drive circuit regions 350 (see FIG. 1), the peripheral circuit region 360 and the silicon through-electrodes 400 are disposed on the obverse surface of the semiconductor CMOS chip 202 (depictions of the detailed structures of these regions are omitted from the drawing).

Interlayer insulating films 910 are disposed in such a way as to cover the sense amplifier circuit regions 340, the word line drive circuit regions 350, the peripheral circuit region 360 and the silicon through-electrodes 400, and the contacts 700 are disposed penetrating through the interlayer insulating films 910 in such a way as to connect electrically to the sense amplifier circuit regions 340, the word line drive circuit regions 350, the peripheral circuit region 360 and the silicon through-electrodes 400. Wiring lines 800 are disposed on and electrically connected to the contacts 700. Here, the interlayer insulating films 910 and the wiring lines 800 may be provided repeatedly in any number of layers (here, three layers). A protective insulating film 920 is disposed in such a way as to cover the interlayer insulating films 910 and the wiring lines 800, and the CMOS chip connection terminals 520 are disposed penetrating through the protective insulating film 920, electrically connected to the wiring lines 800. Further, the positioning protuberance 610 and the positioning hole 620 are disposed on the obverse surface of the protective insulating film 920.

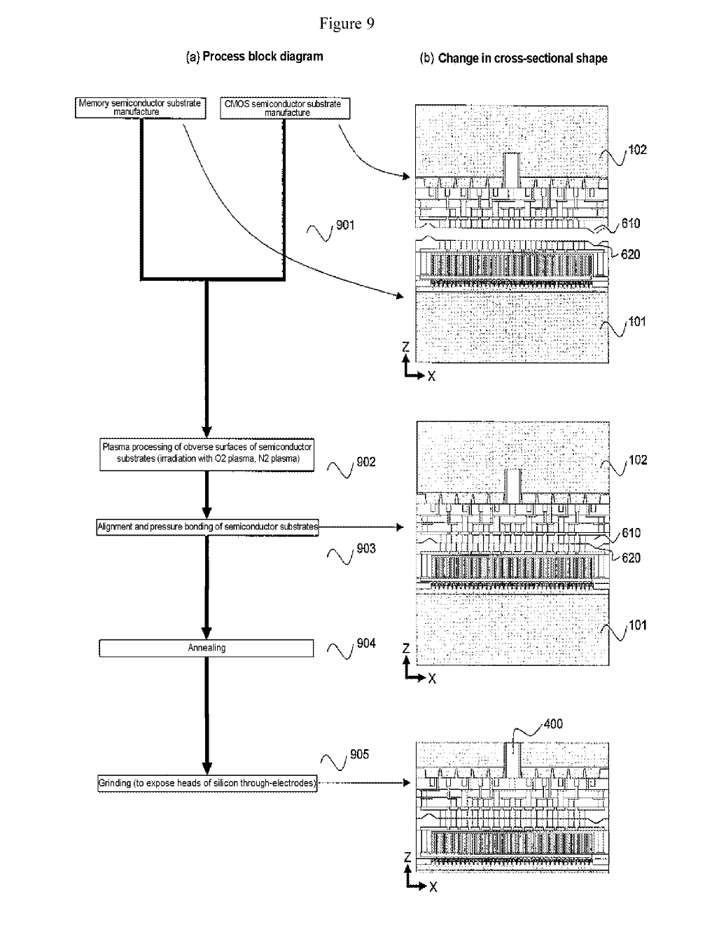

A method of manufacturing the semiconductor device 1 according to an embodiment of the present invention will next be described with reference to FIG. 9. Here FIG. 9 (a) is a process block diagram of the manufacturing process in the present invention, and FIG. 9 (b) is a drawing illustrating changes in a cross-section during the manufacturing process of the present invention.

First, the memory semiconductor substrate 101 and the CMOS semiconductor substrate 102 are manufactured using different processes (step 901). Here, these processes employ known techniques, and details thereof are therefore omitted.

The memory cell region 310, and the sense amplifier circuit region 340, the word line drive circuit region 350 and the peripheral circuit regions 360 can be formed using separate processes, and therefore semiconductor process constraints are eliminated, and it is possible to suppress deteriorations in performance and increases in the manufacturing cost.

Next, the obverse surfaces of the memory semiconductor substrate 101 and the CMOS semiconductor substrate 102 are subjected to plasma processing (for example irradiation with O2 plasma and N2 plasma) using a known method (step 902).

Grid alignment of the IR marks is then performed, and the obverse surfaces of the memory semiconductor substrate 101 and the CMOS semiconductor substrate 102 are bonded together in such a way that the respective positioning protuberances 610 and positioning holes 620 mate (step 903).

As illustrated in FIG. 9, positioning protuberances and positioning holes are formed on both the memory semiconductor substrate 101 and the CMOS semiconductor substrate 102, but it is also possible for the positioning protuberance to be formed only on the memory semiconductor substrate 101 and for the positioning hole recess to be formed only on the CMOS semiconductor substrate 102, or for the positioning protuberance to be formed only on the CMOS semiconductor substrate 102 and for the positioning hole recess to be formed only on the memory semiconductor substrate 101.

Annealing is then performed (at 200° C. in an N2 atmosphere for 1 hour, in an annealing furnace at atmospheric pressure, for example) using a known method (step 904).

The reverse surface of the CMOS semiconductor substrate 102 (the upper surface in the drawing) is then ground to expose the surfaces of the silicon through-electrodes 400, allowing them to serve as electrode terminals (step 905).

This completes the semiconductor device 1 according to an embodiment of the present invention.

### Second Mode of Embodiment of the Present Invention

A second mode embodiment of the present invention will now be described.

A DRAM, which is a semiconductor device, comprises a memory cell region having a capacitor structure, and a peripheral circuit region comprising CMOS circuits. With the progress of miniaturization, differences have arisen in the manufacturing processes for the respective regions, and thus if the regions are manufactured on the same wafer, there are problems in that semiconductor process constraints cause a deterioration in their respective performances, and the manufacturing cost also increases.

Accordingly, in the abovementioned first mode of embodiment, a memory semiconductor substrate on which a plurality of semiconductor memory chips having only a memory cell region are disposed lengthwise and crosswise, and a CMOS semiconductor substrate on which a plurality of semiconductor CMOS chips, having sense amplifier circuit regions, word line drive regions, peripheral circuit regions and silicon through-electrodes, are disposed lengthwise and crosswise, are manufactured using separate manufacturing processes. However, in the abovementioned first mode of embodiment the wiring lines from the memory cells to the sense amplifiers (SA) are long and are liable to affected by noise.

Accordingly, the second mode of embodiment of the present invention provides, as an improved example of the first mode of embodiment of the present invention, a semiconductor device with which the effects of noise can be reduced.

In a memory chip, bit lines and word lines are electrically connected, by way of contacts and wiring lines, respectively to connection terminals exposed at the surface of a semiconductor substrate. Now, the contacts are surrounded by capacitative electrodes, and a bit line leader line and a bit line leader line from an adjacent bank are output as a pair. Output signals are fed to a sense amplifier transistor provided on a CMOS chip.

In other words, the memory chip is connected by way of leader contact plugs to connection terminals that are exposed at the surface. The contact plugs are surrounded, with the interposition of a protective insulating film, by capacitative electrodes (upper electrodes), which form capacitors. By being surrounded by the capacitative electrodes which have a fixed electric potential, the contact plugs are more resistant to noise.

Bit lines are output by outputting a bit line leader line and a bit line leader line from an adjacent bank as a pair. When data are being read from a particular bank, the adjacent bank is in a stand-by state and the electric potential of the wiring line connected to the bit line of the adjacent bank is therefore fixed, and the effects of noise can thus be reduced.

The memory cell region and the peripheral circuit regions can thus be formed separately, and therefore the second mode of embodiment of the present invention is not susceptible to semiconductor process constraints. Manufacturing costs can also be suppressed.

Further, a bit line leader line and a bit line leader line from an adjacent bank are output as a pair, and therefore when data are being read from a particular bank, the adjacent bank is in a stand-by state and the electric potential of the wiring line connected to the bit line of the adjacent bank is therefore fixed, and the effects of noise can thus be reduced. By being surrounded by the capacitative electrodes which have a fixed electric potential, the contact plugs are more resistant to noise.

The second mode of embodiment of the present invention will now be described in detail with reference to the drawings.

The configuration in FIG. 1 to FIG. 3 is the same as in the first mode of embodiment, and a description thereof is thus omitted.

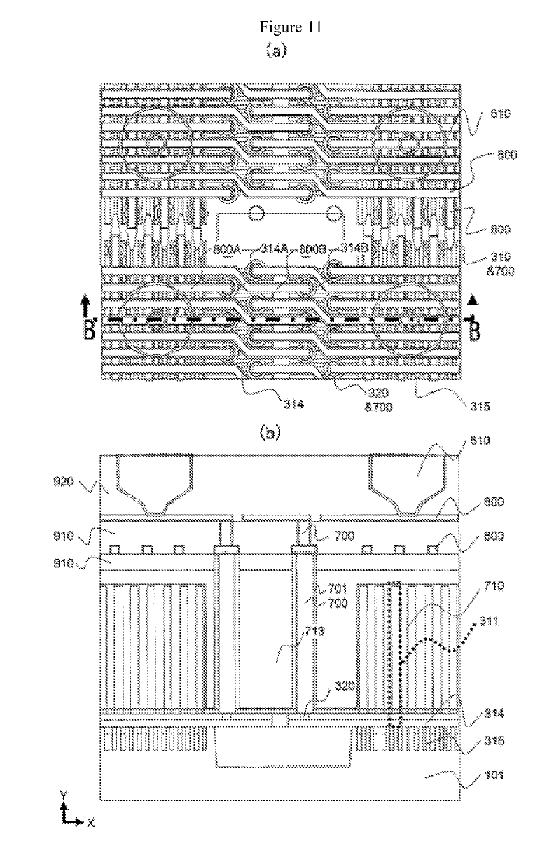

The configuration of the second mode of embodiment of the present invention will now be described in detail with reference to FIGS. 11 (a) and (b). Here, FIG. 11 (a) is an enlarged view of the portion A in FIG. 3 (b), and FIG. 11 (b) is a cross-sectional view along B-B in FIG. 11 (a).

As illustrated in FIG. 11 (a), the bit line connection terminals 320 and the word line connection terminals 330 (which are not shown in the drawings) are disposed in positions that do not interfere with the memory cells 311, for example at end portions of the bit lines 314 and the word lines 315. Contacts 700 are disposed connected to the upper surfaces of the bit line connection terminals 320 and the word line connection terminals 330. The memory chip connection terminals 510 are disposed in positions such that they connect to the upper surfaces of contacts 700 via wiring lines 800 and other contacts 700.

Here, the configuration is such that alternate bit lines 314 are extended, and bit lines 314A of a subject bank and bit lines 314B of an adjacent bank are connected to wiring lines 800A and wiring lines 800B, which form a pair. By this means, when data are being read from the subject bank, the adjacent bank is in a stand-by state and the electric potential of the wiring line 800B connected to the bit line 314B of the adjacent bank is therefore fixed, and the effects of noise can thus be reduced. Signals output from the bit lines 314 are fed to a sense amplifier transistor provided on a CMOS chip.

As illustrated in FIG. 11 (b), the word lines 315 and the bit lines 314, extending in a direction intersecting the word lines 315, are disposed in such a way as to be embedded in the memory semiconductor substrate 101. One memory cell 311 is disposed at each point of intersection between the bit lines 314 and the word lines 315. Only capacitors 710 in the upper portions of the memory cells 311 are illustrated in FIG. 11 (b). Further, the bit line connection terminals 320 are disposed in positions that do not interfere with the memory cells 311, for example at the end portions of the bit lines 314.

Although not illustrated in the drawings, the word line connection terminals 330 are also disposed in positions that do not interfere with the memory cells 311, for example at the end portions of the word lines 315. The bit line connection terminals 320 and the word line connection terminals 330 are electrically connected in a one-to-one relationship to the memory chip connection terminals 510, via the wiring lines 800 and the contacts 700 which penetrate through a plurality of interlayer insulating films 910. Here, the contacts 700 (for example a tungsten film) are covered by capacitative electrodes 713 (for example a titanium nitride film with a polysilicon film thereon), with a protective insulating film 701 (for example a silicon dioxide film) interposed therebetween. Now, the capacitative electrodes 713 have a fixed electric potential, and therefore the effects of noise can be reduced.

### Third Mode of Embodiment of the Present Invention

A third mode embodiment of the present invention will now be described.

A DRAM, which is a semiconductor device, comprises a memory cell region having a capacitor structure, and a peripheral circuit region comprising CMOS circuits. With the progress of miniaturization, differences have arisen in the manufacturing processes for the respective regions, and thus if the regions are manufactured on the same wafer, there are problems in that semiconductor process constraints cause a deterioration in their respective performances, and the manufacturing cost also increases.

Accordingly, in the abovementioned first mode of embodiment, a memory semiconductor substrate on which a plurality of semiconductor memory chips having only a memory cell region are disposed lengthwise and crosswise, and a CMOS semiconductor substrate on which a plurality of semiconductor CMOS chips, having sense amplifier circuit regions, word line drive regions, peripheral circuit regions and silicon through-electrodes, are disposed lengthwise and crosswise, are manufactured using separate manufacturing processes. However, the wiring lines from the memory cells to the sense amplifiers (SA) are long and are liable to affected by noise.

Accordingly, the third mode of embodiment of the present invention provides, as an improved example of the abovementioned first mode of embodiment, a semiconductor device with which the effects of noise can be reduced.

In a semiconductor CMOS chip, terminals in sense amplifier circuit regions, word line drive regions and peripheral circuit regions, and that are connected to memory cells, are electrically connected, by way of contacts and wiring lines, respectively to connection terminals exposed at the surface of a semiconductor substrate. Further, peripheral circuits that electrically connect the completed semiconductor device to external circuits are electrically connected to corresponding silicon through-electrodes by way of contacts and wiring lines. Here, sense amplifier transistors are disposed directly below connection terminals connected to bit lines, sub-word drivers are disposed directly below connection terminals connected to word lines, and main word lines and global bit lines are formed in the same layer as the connection terminals or in the immediately lower layer. Further, in each wiring line layer, contact plugs of the bit lines connected to the sense amplifier transistors are sandwiched between ground lines (GND lines).

In other words, the global bit lines are disposed in the same layer as the connection terminals, and the main word lines are disposed in the layer below said layer (the global bit lines and the main word lines may be inverted). One layer can be eliminated by disposing the connection terminals and the wiring line layer in the same layer rather than in separate layers. The contact plugs connected to the bit lines are sandwiched between ground lines (GND lines). Because there are fixed ground potentials next to the contact plugs of the bit lines connected to the sense amplifier transistors, the effects of noise can be reduced. Moreover, by disposing the sense amplifier transistors directly below the connection terminals, the distance from the connection terminal to the sense amplifier transistor can be reduced.

The memory cell region and the peripheral circuit regions can thus be formed separately, and therefore the third mode of embodiment of the present invention is not susceptible to semiconductor process constraints. Manufacturing costs can also be suppressed. Further, because there are fixed ground potentials next to the contact plugs of the bit lines connected to the sense amplifier transistors, the effects of noise can be reduced. Further, by disposing the memory cells, the sense amplifier transistors and the word line drive transistors directly below the connection terminals, the distance between wiring lines can be reduced.

The third mode of embodiment of the present invention will now be described in detail with reference to the drawings.

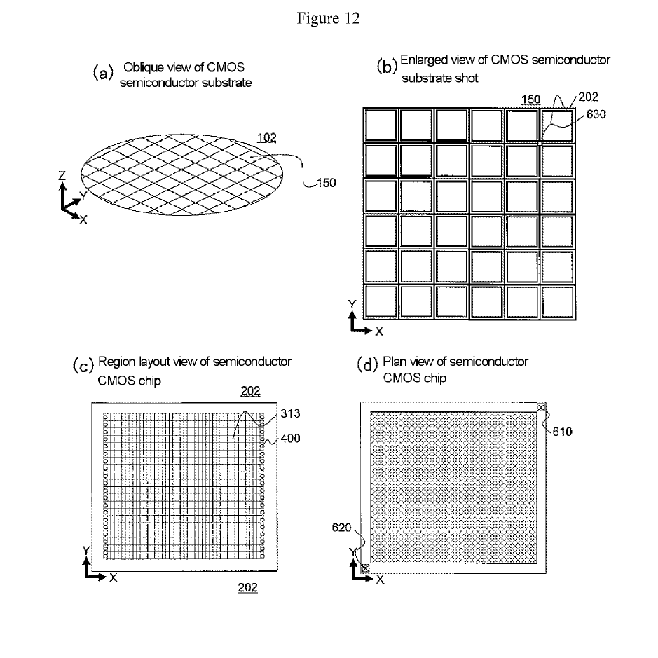

First, the structure of the CMOS semiconductor substrate 102 in the third mode of embodiment of the present invention will be described with reference to FIG. 12 to FIG. 18.

FIG. 12 (a) is an oblique view of the CMOS semiconductor substrate 102.

Semiconductor CMOS chips 202 are disposed in a planar manner in the X-direction and the Y-direction on the obverse surface of the CMOS semiconductor substrate 102. Here, in connection with light exposure during the semiconductor manufacturing process, a plurality of semiconductor CMOS chips 202 (20 to 40 chips, for example 36 chips) are managed as a shot 150.

FIG. 12 (b) is an enlarged view of a shot 150 in the CMOS semiconductor substrate 102.

An IR mark 630 (one or more marks, for example one mark) for grid alignment during lamination of the plurality of semiconductor CMOS chips 202 and the semiconductor substrate, is disposed on the shot 150.

Here, the IR mark 630 is disposed in a position that overlaps the IR mark 630 on the memory semiconductor substrate 101, discussed hereinabove, when the obverse surfaces of the memory semiconductor substrate 101 and the CMOS semiconductor substrate 102 are laminated together.

FIG. 12 (c) is a region layout view of the semiconductor CMOS chip 202.

A plurality (100 for example) of CMOS banks 313 are disposed over substantially the entire surface of the semiconductor CMOS chip 202. Of the CMOS banks 313, the CMOS banks 313 at the end portions of the semiconductor CMOS chip 202 have one or two silicon through-electrodes 400.

FIG. 12 (d) is a plan view of the semiconductor CMOS chip 202.

The CMOS banks 313 discussed hereinabove are hidden beneath an interlayer insulating film and a protective insulating film which are discussed hereinafter. A positioning protuberance 610 and a positioning hole 620 (referred to collectively as a positioning construction 600) are disposed on the obverse surface of an outer peripheral portion of the semiconductor CMOS chip 202. The positioning construction 600 is disposed in a position such that, when the obverse surfaces of the memory semiconductor substrate 101 and the CMOS semiconductor substrate 102 are laminated together, the positioning protuberance 610 mates with the positioning hole 620 in the memory semiconductor substrate 101 discussed hereinabove, and the positioning hole 620 mates with the positioning protuberance 610 on the memory semiconductor substrate 101 discussed hereinabove. It should be noted that the positioning construction 600 may be omitted if the accuracy of the grid alignment using the IR marks 630 is high.

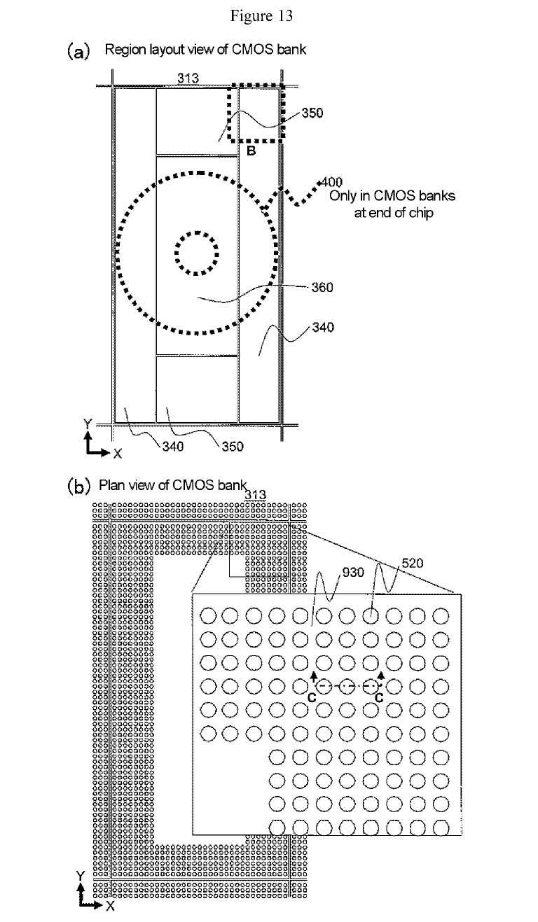

FIG. 13 (a) is a region layout view of the semiconductor CMOS bank 313.

A peripheral circuit region 360, sense amplifier circuit regions 340 and word line drive circuit regions (regions in which circuits known as sub-word drivers are disposed) 350 are disposed in each CMOS bank 313, and silicon through-electrodes 400 are additionally disposed in the CMOS banks 313 at the end portions of the semiconductor CMOS chip 202.

FIG. 13 (b) is a plan view of the semiconductor CMOS bank 313.

The peripheral circuit regions 360, the sense amplifier circuit regions 340, the word line drive circuit regions 350 and the silicon through-electrodes 400, discussed hereinabove, are hidden beneath an interlayer insulating film and a protective insulating film 930, discussed hereinafter. CMOS connection terminals 520 are disposed on the obverse surface of the CMOS bank 313, and are connected to the sense amplifier circuit regions 340 and the word line drive circuit regions 350 by way of wiring lines and contacts, discussed hereinafter. The CMOS connection terminals 520 are disposed in positions such that, when the obverse surfaces of the memory semiconductor substrate 101 and the CMOS semiconductor substrate 102 are laminated together, the CMOS chip connection terminals 520 electrically connect to the memory chip connection terminals 510 on the memory semiconductor substrate 101, discussed hereinabove.

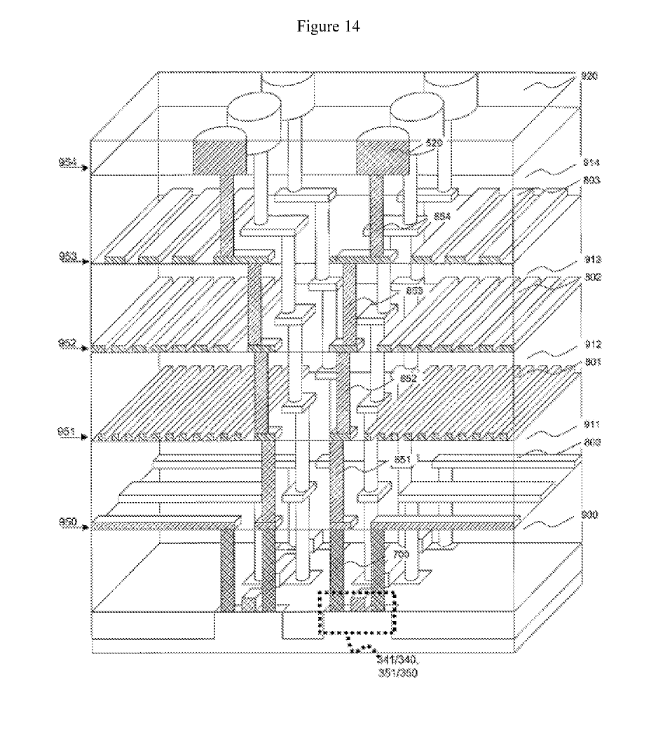

FIG. 14 is a schematic diagram illustrating three-dimensionally a portion in the vicinity of the cross-section C-C in FIG. 13 (b). Parts that are not related to this mode of embodiment are omitted from the drawing or are simplified.

As illustrated in FIG. 14, there are multiple wiring line layers (four layers in this mode of embodiment), and sense amplifier transistors 341 in the sense amplifier circuit regions 340 are connected to the CMOS connection terminals 520 by the shortest path, by way of a contact 700, a local wiring line 800, a first via 851, a first wiring line 801, a second via 852, a second wiring line 802, a third via 853, a third wiring line 803 and a fourth via 854. In other words, the sense amplifier transistor 341 connected to the CMOS connection terminal 520 is disposed substantially directly below said CMOS connection terminal 520. Similarly, word line drive transistors are also disposed substantially directly below the CMOS connection terminals 520.

In the following description, wiring lines themselves are referred to using numbers from 800, and layers in which said wiring lines are disposed are referred to using numbers from 950, the wiring line layers being called, in order from the bottom, a local wiring line layer 950, a first wiring line layer 951, a second wiring line layer 952 and a third wiring line layer 953. The wiring lines 800 in the local wiring line layer 950 are disposed on an interlayer insulating film 900 and are connected to the sense amplifier transistors 341 by way of contact plugs 700 which penetrate through the interlayer insulating film 900, and said wiring lines 800 are embedded in an inter wiring-layer insulating film 911.

The first wiring lines 801 in the first wiring line layer 951 are disposed on the inter wiring-layer insulating film 911 and are connected to the wiring lines 800 in the local wiring line layer 950 by way of the first vias 851 which penetrate through the inter wiring-layer insulating film 911, and said first wiring lines 801 are embedded in an inter wiring-layer insulating film 912.

The second wiring lines 802 in the second wiring line layer 952 are disposed on the inter wiring-layer insulating film 912 and are connected to the first wiring lines 801 in the first wiring line layer 951 by way of the second vias 852 which penetrate through the inter wiring-layer insulating film 912, and said second wiring lines 802 are embedded in an inter wiring-layer insulating film 913.

The third wiring lines 803 in the third wiring line layer 953 are disposed on the inter wiring-layer insulating film 913 and are connected to the second wiring lines 802 in the second wiring line layer 952 by way of the third vias 853 which penetrate through the inter wiring-layer insulating film 913, and said third wiring lines 803 are embedded in an inter wiring-layer insulating film 914.

Fourth vias 854 penetrate through the inter wiring-layer insulating film 914 and are connected to the third wiring lines 803 in the third wiring line layer 953, and the CMOS connection terminals 520 are disposed in such a way as to be connected to the upper surfaces of the fourth vias 854. A protective insulating film 920 is disposed between the CMOS connection terminals 520.

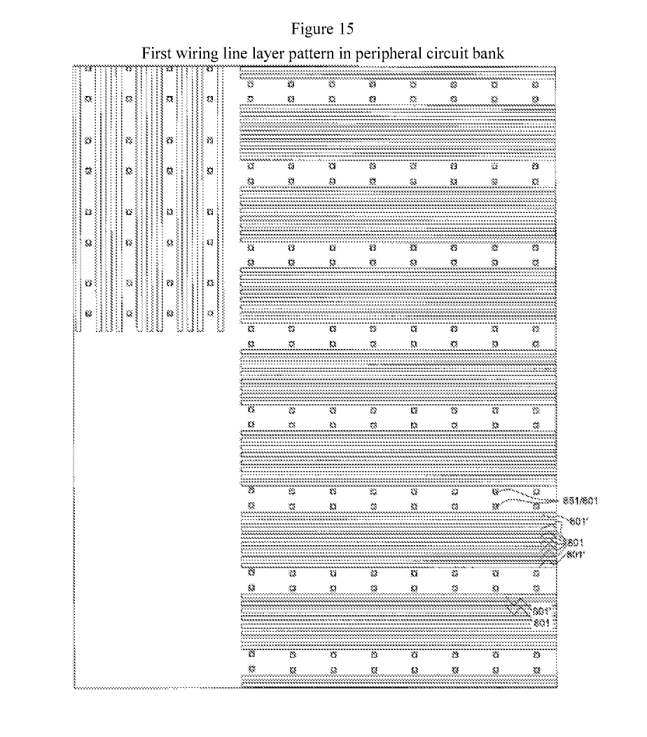

FIG. 15 illustrates the wiring line pattern in the first wiring line layer 951 in a corner portion of a peripheral circuit bank.

Pairs of two first vias 851 and two first wiring lines 801 connected to the first vias 851, adjacent to each other in the vertical direction in the drawing, are formed, and first wiring lines (GND) 801′ are disposed on either side of the pairs of first wiring lines 801. A plurality of first wiring lines 801 are disposed on the side of the first wiring line (GND) 801′ that is opposite to the pairs of first wiring lines 801 (between the first wiring lines (GND) 801′), but as they are not related to this patent a description thereof is omitted. Further, first wiring lines 801 and first vias 851 that are not illustrated in the drawing also exist in the regions that are empty in the drawing, but as these are not related to this mode of embodiment they are omitted.

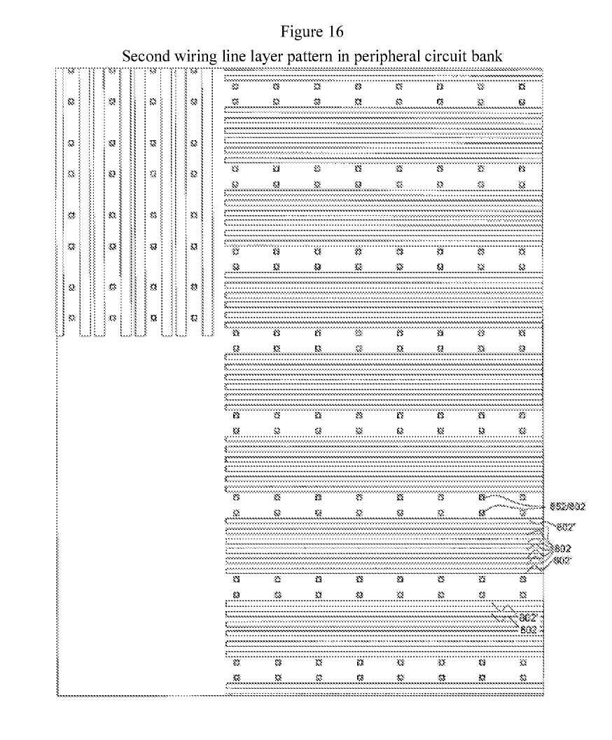

FIG. 16 illustrates the wiring line pattern in the second wiring line layer 952 in a corner portion of a peripheral circuit bank.

The second wiring lines 802 connected to the second vias 852 form pairs, and second wiring lines (GND) 802′ are disposed on either side of the pairs of second wiring lines 802. Second vias 852 are also connected to the other second wiring lines 802, but as they are not related to this mode of embodiment they are omitted. Further, second wiring lines 802 and second vias 852 also exist in the regions that are empty in the drawing, but as these are not related to this mode of embodiment they are omitted.

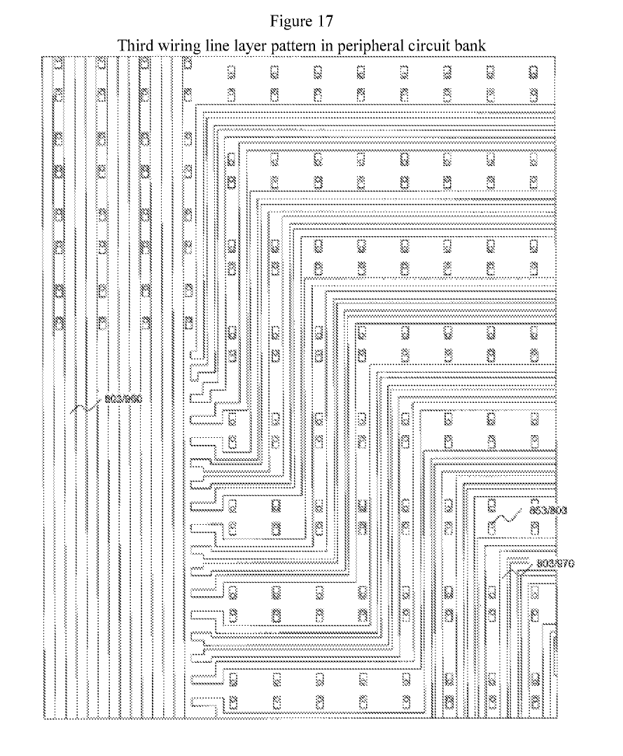

FIG. 17 illustrates the wiring line pattern in the third wiring line layer 953 in a corner portion of a peripheral circuit bank.

The third wiring lines 803 connected to the third vias 853 form pairs, and third wiring lines 803 are disposed as global bit lines 970, threaded through gaps between the pairs of third wiring lines 803. Here, the global bit lines 970 are wiring lines that are connected to a plurality of peripheral circuit banks, and that connect bit line information to peripheral circuits which serve as an interface to the outside.

Further, third wiring lines 803 are disposed as main word lines 960 in such a way as to extend in the Y-direction between third vias 853 that are connected to the word line drive regions. Here, the main word lines 960 are wiring lines that are connected to a plurality of peripheral circuit banks, and that connect word line information to peripheral circuits which serve as an interface to the outside.

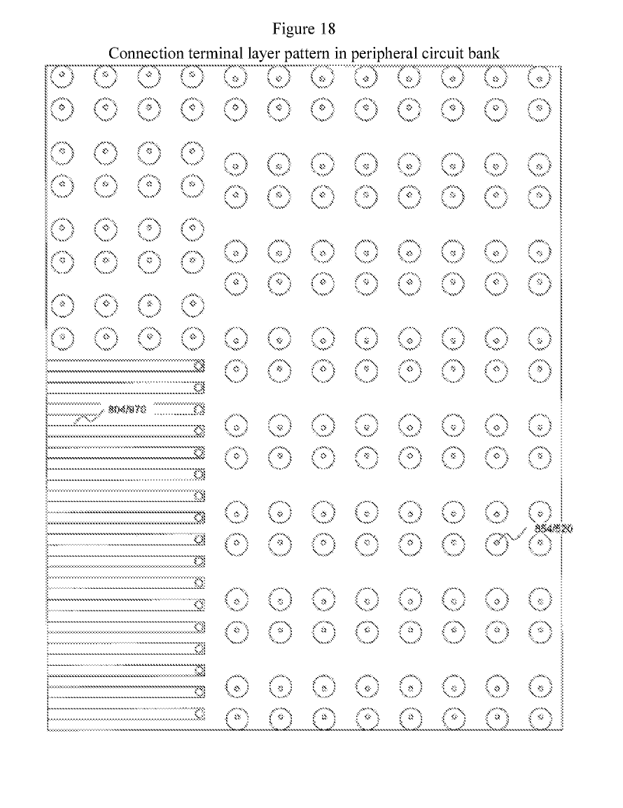

FIG. 18 illustrates the wiring line pattern in the connection terminal layer 954 in the corner portion of the peripheral circuit bank.

The connection terminals 520 connected to the fourth vias 854 form pairs. In order to cross the main word lines 960 discussed hereinabove, fourth wiring lines 804 are disposed as global bit lines 970 in the region with no connection terminals 520, and are connected to the global bit lines 970 in the third wiring line layer by way of the fourth vias 854.

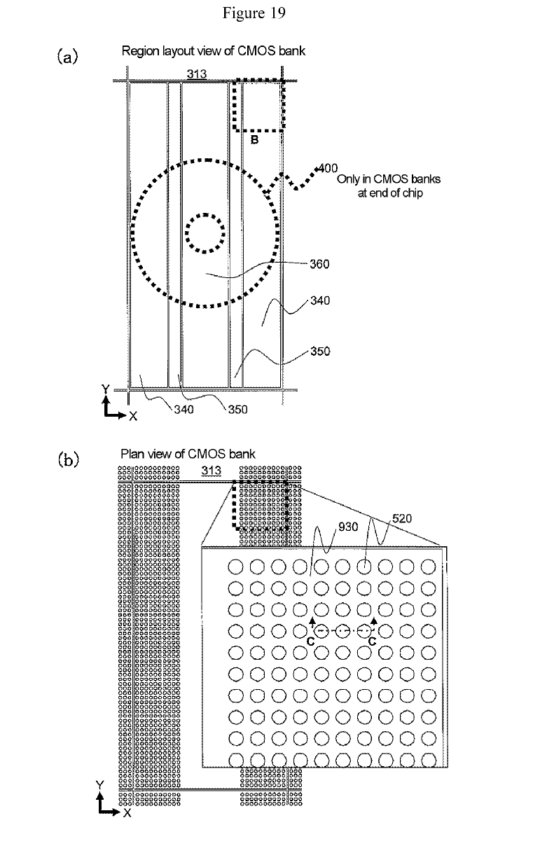

A modified example (variation) of the structure of the CMOS semiconductor substrate 102 in the third mode of embodiment will now be described with reference to FIG. 19 to FIG. 24. The configuration in FIG. 12 is the same as in the abovementioned mode of embodiment, and a description thereof is therefore omitted.

FIG. 19 (a) is a region layout view of the semiconductor CMOS bank 313.

A peripheral circuit region 360, sense amplifier circuit regions 340 and word line drive circuit regions 350 are disposed in each CMOS bank 313, and silicon through-electrodes 400 are additionally disposed in the CMOS banks 313 at the end portions of the semiconductor CMOS chip 202.

FIG. 19 (b) is a plan view of the semiconductor CMOS bank 313.

The peripheral circuit regions 360, the sense amplifier circuit regions 340, the word line drive circuit regions 350 and the silicon through-electrodes 400, discussed hereinabove, are hidden beneath an interlayer insulating film and a protective insulating film 930, discussed hereinafter. CMOS connection terminals 520 are disposed on the obverse surface of the CMOS bank 313, and are connected to the sense amplifier circuit regions 340 and the word line drive circuit regions 350 by way of wiring lines and contacts, discussed hereinafter. The CMOS connection terminals 520 are disposed in positions such that, when the obverse surfaces of the memory semiconductor substrate 101 and the CMOS semiconductor substrate 102 are laminated together, the CMOS chip connection terminals 520 electrically connect to the memory chip connection terminals 510 on the memory semiconductor substrate 101, discussed hereinabove.

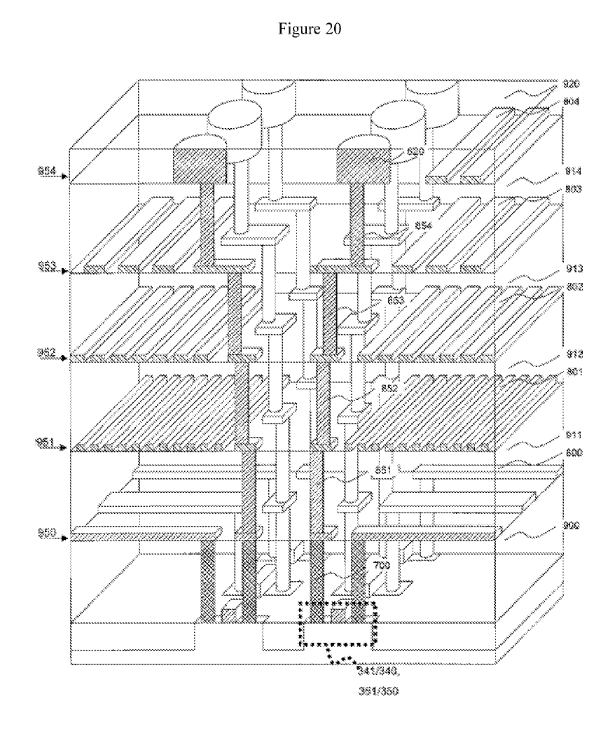

FIG. 20 is a schematic diagram illustrating three-dimensionally a portion in the vicinity of the cross-section C-C in FIG. 19 (b). Parts that are not related to this mode of embodiment are omitted from the drawing or are simplified.

As illustrated in FIG. 20, there are multiple wiring line layers (four layers in this mode of embodiment), and sense amplifier transistors 341 in the sense amplifier circuit regions 340 are connected to the CMOS connection terminals 520 by the shortest path, by way of a contact 700, a local wiring line 800, a first via 851, a first wiring line 801, a second via 852, a second wiring line 802, a third via 853, a third wiring line 803 and a fourth via 854. In other words, the sense amplifier transistor 341 connected to the CMOS connection terminal 520 is disposed directly below said CMOS connection terminal 520. In the following description the wiring line layers are called, in order from the bottom, a local wiring line layer 950, a first wiring line layer 951, a second wiring line layer 952 and a third wiring line layer 953.

The wiring lines 800 in the local wiring line layer 950 are disposed on an interlayer insulating film 900 and are connected to the sense amplifier transistors 341 by way of contact plugs 700 which penetrate through the interlayer insulating film 900, and said wiring lines 800 are embedded in an inter wiring-layer insulating film 911.

The first wiring lines 801 in the first wiring line layer 951 are disposed on the inter wiring-layer insulating film 911 and are connected to the wiring lines 800 in the local wiring line layer 950 by way of the first vias 851 which penetrate through the inter wiring-layer insulating film 911, and said first wiring lines 801 are embedded in an inter wiring-layer insulating film 912.

The second wiring lines 802 in the second wiring line layer 952 are disposed on the inter wiring-layer insulating film 912 and are connected to the first wiring lines 801 in the first wiring line layer 951 by way of the second vias 852 which penetrate through the inter wiring-layer insulating film 912, and said second wiring lines 802 are embedded in an inter wiring-layer insulating film 913.

The third wiring lines 803 in the third wiring line layer 953 are disposed on the inter wiring-layer insulating film 913 and are connected to the second wiring lines 802 in the second wiring line layer 952 by way of the third vias 853 which penetrate through the inter wiring-layer insulating film 913, and said third wiring lines 803 are embedded in an inter wiring-layer insulating film 914.

Fourth vias 854 penetrate through the inter wiring-layer insulating film 914 and are connected to the third wiring lines 803 in the third wiring line layer 953, and the CMOS connection terminals 520 are disposed in such a way as to be connected to the upper surfaces of the fourth vias 854.

A protective insulating film 920 is disposed between the CMOS connection terminals 520.

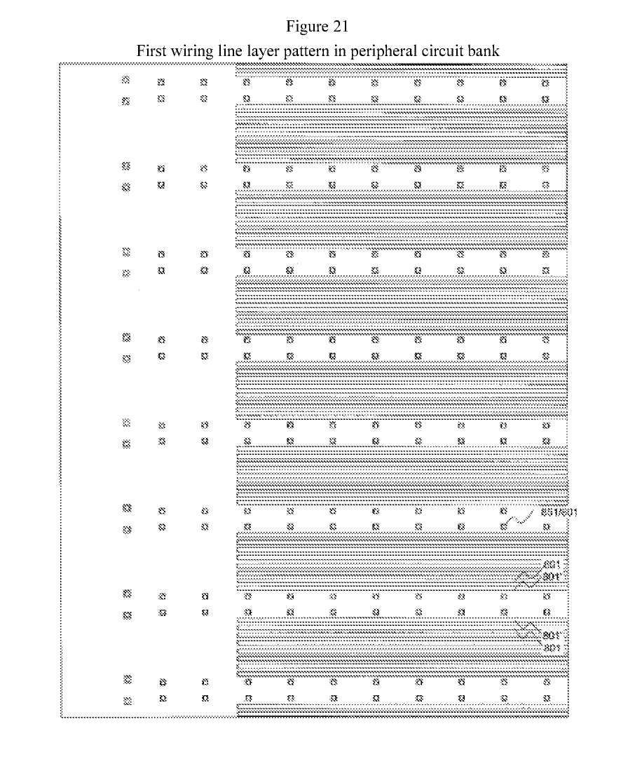

FIG. 21 illustrates the wiring line pattern in the first wiring line layer 951 in a corner portion of a peripheral circuit bank.

Pairs of two first vias 851 and two first wiring lines 801 connected to the first vias 851, adjacent to each other in the vertical direction in the drawing, are formed, and first wiring lines (GND) 801′ are disposed on either side of the pairs of first wiring lines 801. A plurality of first wiring lines 801 are disposed on the side of the first wiring line (GND) 801′ that is opposite to the pairs of first wiring lines 801 (between the first wiring lines (GND) 801′), but as they are not related to this mode of embodiment a description thereof is omitted.

Further, first wiring lines 801 and first vias 851 that are not illustrated in the drawing also exist in the regions that are empty in the drawing, but as these are not related to this mode of embodiment they are omitted.

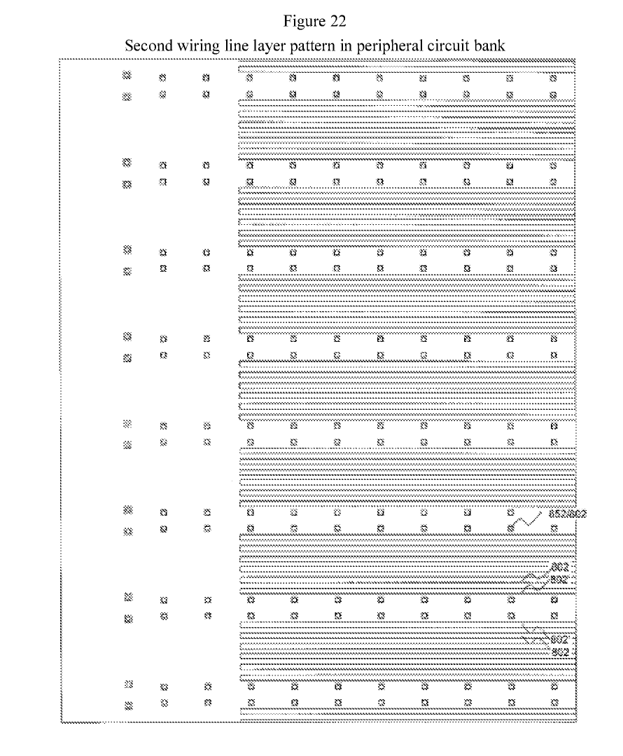

FIG. 22 illustrates the wiring line pattern in the second wiring line layer 952 in a corner portion of a peripheral circuit bank.

The second wiring lines 802 connected to the second vias 852 form pairs, and second wiring lines (GND) 802′ are disposed on either side of the pairs of second wiring lines 802. Second vias 852 are also connected to the other second wiring lines 802, but as they are not related to this mode of embodiment they are omitted. Further, second wiring lines 802 and second vias 852 also exist in the regions that are empty in the drawing, but as these are not related to this mode of embodiment they are omitted.

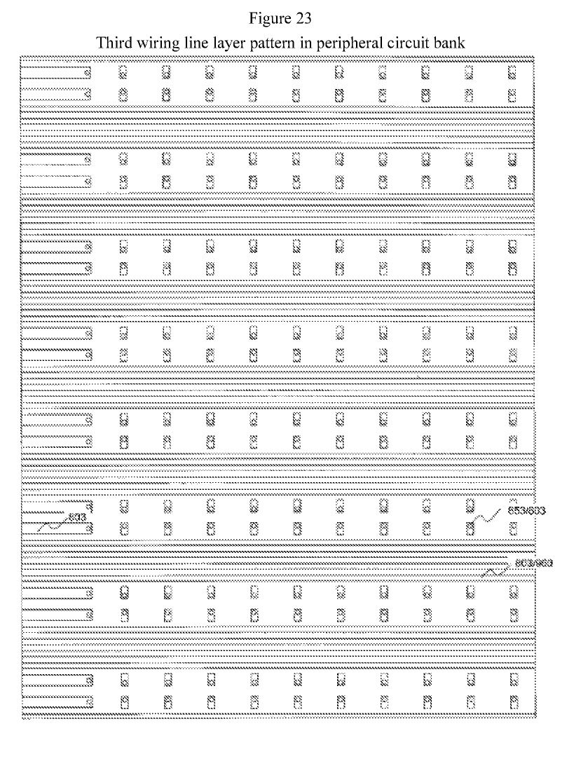

FIG. 23 illustrates the wiring line pattern in the third wiring line layer 953 in a corner portion of a peripheral circuit bank.

The third wiring lines 803 connected to the third vias 853 form pairs, and third wiring lines 803 are disposed as main bit lines 960 extending in the X-direction between the pairs of third wiring lines 803.

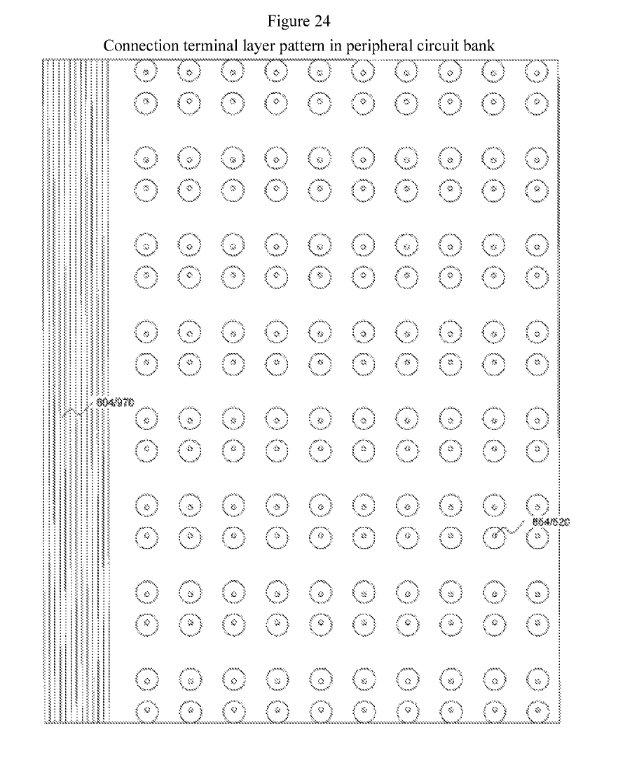

FIG. 24 illustrates the wiring line pattern in the connection terminal layer 954 in the corner portion of the peripheral circuit bank.

The connection terminals 520 connected to the fourth vias 854 form pairs. In the region in which there are no connection terminals 520, fourth wiring lines 804 are disposed as global bit lines 970 extending in the Y-direction.

In the first example, the peripheral circuit region is surrounded from four directions by the sense amplifier circuit regions and the word line drive regions, but in the second example, as illustrated in FIG. 2 e, the peripheral circuit region is not surrounded from four directions, and therefore there is more freedom in the arrangement of wiring lines.

It should be noted that, in the reverse of the wiring line configuration illustrated in the abovementioned modes of embodiment, the third wiring lines 803 may form the global bit lines, and the fourth wiring lines 804 may form the main word lines.

### Fourth Mode of Embodiment of the Present Invention

A fourth mode embodiment of the present invention will now be described.

A DRAM, which is a semiconductor device, comprises a memory cell region having a capacitor structure, and a peripheral circuit region comprising CMOS circuits. With the progress of miniaturization, differences have arisen in the manufacturing processes for the respective regions, and thus if the regions are manufactured on the same wafer, there are problems in that semiconductor process constraints cause a deterioration in their respective performances, and the manufacturing cost also increases.

Accordingly, in the abovementioned first mode of embodiment, a memory semiconductor substrate on which a plurality of semiconductor memory chips having only a memory cell region are disposed lengthwise and crosswise, and a CMOS semiconductor substrate on which a plurality of semiconductor CMOS chips, having sense amplifier circuit regions, word line drive regions, peripheral circuit regions and silicon through-electrodes, are disposed lengthwise and crosswise, are manufactured using separate manufacturing processes. However, the wiring lines from the memory cells to the sense amplifiers are long and are liable to affected by noise.

Accordingly, the fourth mode of embodiment of the present invention provides, as an improved example of the abovementioned first mode of embodiment, a semiconductor device with which the effects of noise can be reduced.

In the fourth mode of embodiment of the present invention, the bit lines and the word lines are led out to the reverse surface of the memory semiconductor substrate by way of bit line connection plugs and word line connection plugs, and are electrically connected by way of contact plugs and wiring lines to connection terminals exposed at the reverse surface of the memory semiconductor substrate. Now, a bit line leader line and a bit line leader line from an adjacent bank are output as a pair.

In other words, in the abovementioned first mode of embodiment, the connection terminals are led out to the obverse surface side of the memory semiconductor chip, but here, the connection terminals are led out by way of contact plugs and wiring lines to the reverse surface side of the memory semiconductor chip. The wiring line length can thus be reduced compared with a case in which the connection terminals are led out from the obverse surface, and leading out the contact plugs, connected to the bit lines, from the side opposite to the side on which the capacitors are provided has the effect of reducing the parasitic capacitance between the capacitors and the bit lines, and reducing the effects of noise.

The memory cell region and the peripheral circuit regions can thus be formed separately, and therefore the fourth mode of embodiment of the present invention is not susceptible to semiconductor process constraints. Manufacturing costs can also be suppressed. Further, the distance from the bit lines and the word lines to the connection terminals is reduced, and leading out the contact plugs, connected to the bit lines, from the side opposite to the side on which the capacitors are provided has the effect of reducing the parasitic capacitance between the capacitors and the bit lines, and reducing the effects of noise.

The fourth mode of embodiment of the present invention will now be described in detail with reference to the drawings.

The configuration in FIG. 1, FIG. 2, and FIGS. 3 (a) and (b) is the same as in the first mode of embodiment, and a description thereof is thus omitted.

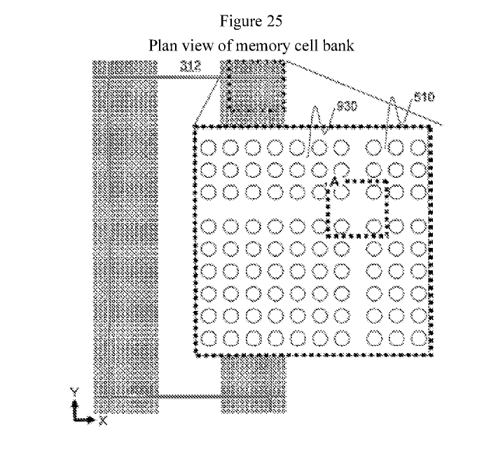

The fourth mode of embodiment of the present invention will now be described with reference to FIG. 25 to FIG. 30.

FIG. 25 is a plan view of a memory cell bank 312 according to a fourth mode of embodiment of the present invention.

The memory cells 311, the bit lines 314, the word lines 315, the bit line connection plugs 320 and the word line connection plugs 330, discussed hereinabove, are hidden beneath an interlayer insulating film and a protective insulating film 930, discussed hereinafter. Memory chip connection terminals 510 are disposed on the obverse surface of the memory cell bank 312, and are connected in a one-to-one relationship to the bit line connection plugs 320 and the word line connection plugs 330 by way of wiring lines and contacts, discussed hereinafter. The memory chip connection terminals 510 are disposed in positions such that, when the obverse surfaces of the memory semiconductor substrate 101 and the CMOS semiconductor substrate 102 are laminated together, the memory chip connection terminals 510 electrically connect to CMOS connection terminals 520 on the CMOS semiconductor substrate 102, discussed hereinafter.

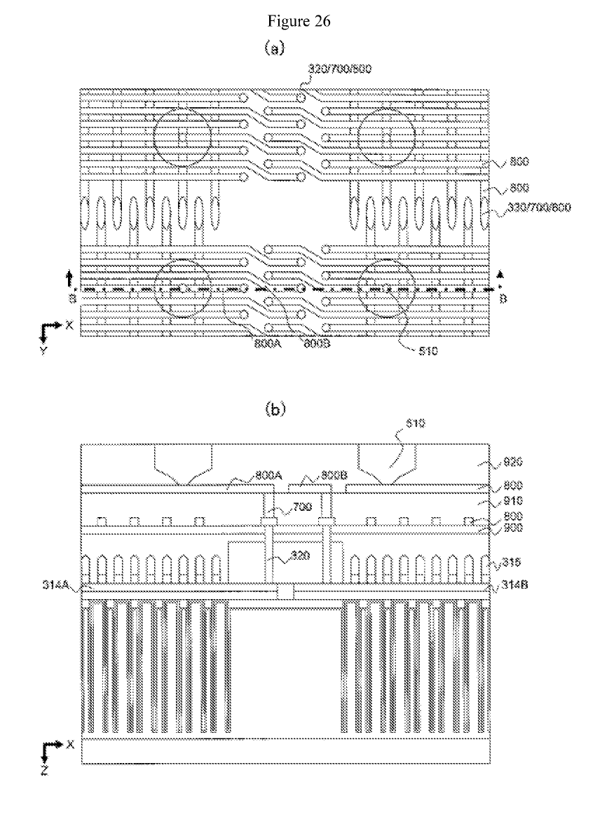

FIG. 26 (a) is an enlarged sectional view of the portion A in FIG. 25.

The bit line connection plugs 320 and the word line connection plugs 330 are disposed at the end portions of bit lines 314 and word lines 315, which are not shown in the drawing. Contacts 700 are disposed connected to the upper surfaces of the bit line connection plugs 320 and the word line connection plugs 330. The memory chip connection terminals 510 are disposed in positions such that they connect to the upper surfaces of contacts 700 via wiring lines 800 and other contacts 700. Here, the configuration is such that alternate bit lines 314 are extended, and bit lines 314A of a subject bank and bit lines 314B of an adjacent bank are connected, by way of contacts 700 and wiring lines 800, to wiring lines 800A and wiring lines 800B, which form a pair. By this means, when data are being read from the subject bank, the adjacent bank is in a stand-by state and the electric potential of the wiring line 800B connected to the bit line 314B of the adjacent bank is therefore fixed, and the effects of noise can thus be reduced.

FIG. 26 (b) is a cross-sectional view along B-B in FIG. 26 (a).

The word lines 315 and the bit lines 314, extending in a direction intersecting the word lines 315, are disposed in such a way as to be embedded in the memory semiconductor substrate 101. One memory cell 311 is disposed at each point of intersection between the bit lines 314 and the word lines 315.

Only capacitors 710 in the upper portions of the memory cells 311 are illustrated in FIG. 26 (b). Further, the bit line connection plugs 320 are disposed in positions that do not interfere with the memory cells 311, for example at the end portions of the bit lines 314. Although not illustrated in the drawings, the word line connection plugs 330 are also disposed in positions that do not interfere with the memory cells 311, for example at the end portions of the word lines 315. The bit line connection plugs 320 and the word line connection plugs 330 are electrically connected in a one-to-one relationship to the memory chip connection terminals 510, via the wiring lines 800 and the contacts 700 which penetrate through a plurality of interlayer insulating films 910. Here, the contacts 700 are covered by a capacitative electrode 713, with the interposition of a protective insulating film 701, illustrated in FIG. 3 discussed hereinafter. Now, the capacitative electrodes 713 have a fixed electric potential, and therefore the effects of noise can be reduced.

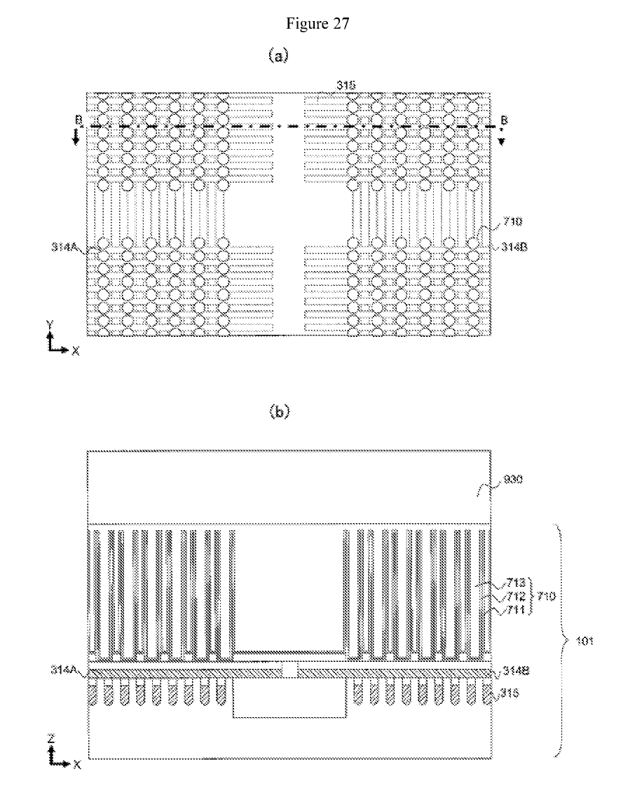

A method of manufacturing the memory semiconductor substrate in this mode of embodiment of the present invention will now be described with reference to FIG. 27 to FIG. 30.

Here, in FIG. 27 to FIG. 30, (a) is a plan view corresponding to FIGS. 26 (a), and (b) is a cross-sectional view corresponding to FIG. 26 (b).

As illustrated in FIGS. 27 (a) and (b), word lines 315, bit lines 314A of the subject bank and bit lines 314B of the adjacent bank, which are bit lines 314, and capacitors 710 comprising a lower electrode 711, a capacitative insulating film 712 and an upper electrode 713 are formed using known methods, after which a support base 930 is affixed to the obverse surface of the memory semiconductor substrate 101.

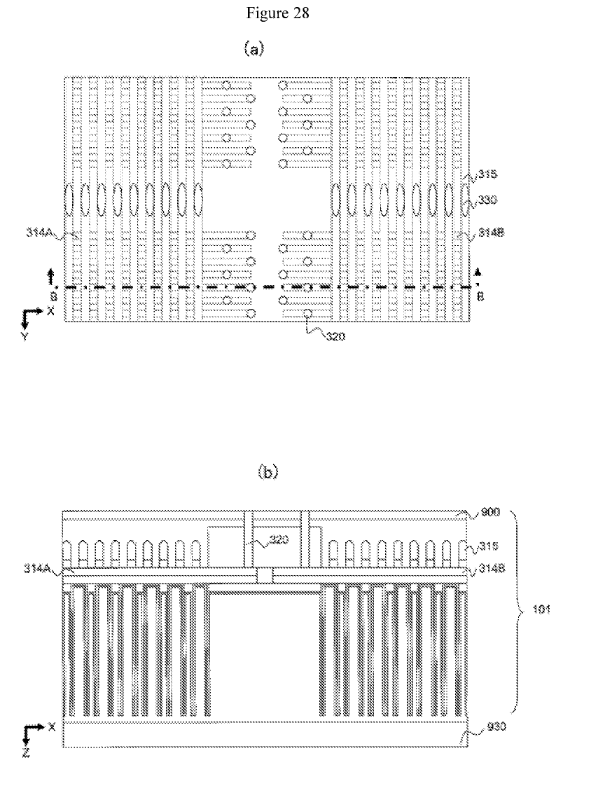

Next, as illustrated in FIGS. 28 (a) and (b), the substrate is inverted (hereafter, the −Z direction in the drawing is the upward direction), and the memory semiconductor substrate 101 is lightly ground (for example 3 to 5 μm).

An interlayer insulating film 900 is then deposited onto the upper surface of the memory semiconductor substrate 101, and bit line connection plugs 320 and word line connection plugs 330 are formed by making openings using lithography and dry etching, and filling the openings with a conductive material, by CVD or the like.

Here, the bit line connection plugs 320 are disposed in two rows aligned in the Y-direction, on alternate bit lines 314A of the subject bank, in such a way as to be connected to the bit lines 314A of the subject bank. Bit line connection plugs 320 are also disposed in the same way with respect to the bit lines 314B in the adjacent bank.

In other words, four rows of bit line connection plugs 320 are disposed between the memory cell banks 312 (which are omitted from the drawing), side-by-side in the X-direction. The word line connection plugs 330 are disposed in such a way as to be connected to the word lines 315 of two memory cell banks 312 (which are omitted from the drawing) that are adjacent to each other in the Y-direction. It should be noted that the bit line connection plugs 320 and the word line connection plugs 330 may be formed before the memory cells are formed, using a known TSV (Through Substrate Via) technique.

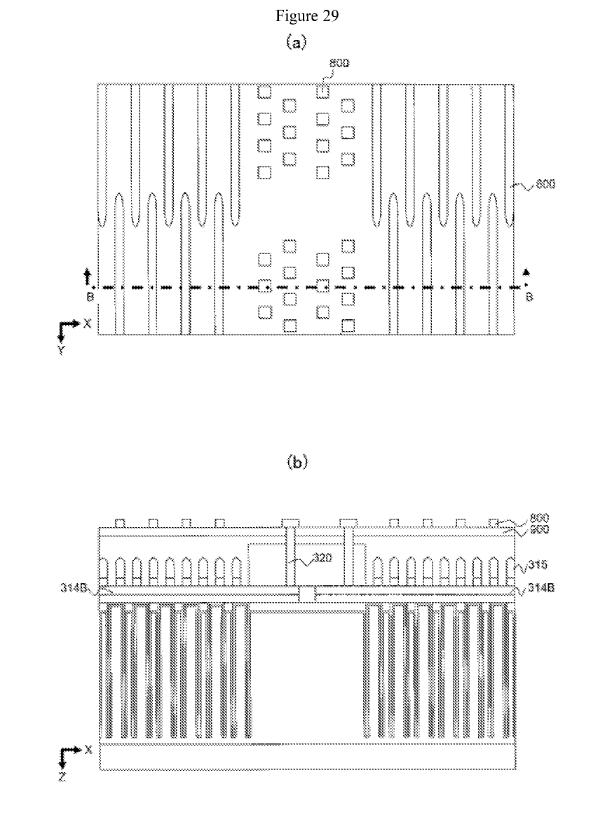

Next, as illustrated in FIGS. 29 (a) and (b), wiring lines 800 are formed in such a way as to be connected to the upper surfaces of the bit line connection plugs 320 and the word line connection plugs 330. Here, the wiring lines 800 connected to the bit line connection plugs 320 are for connecting contact plugs 700, discussed hereinafter, and the wiring lines 800 connected to the word line connection plugs 330 extend alternately in the Y-direction and the −Y-direction.

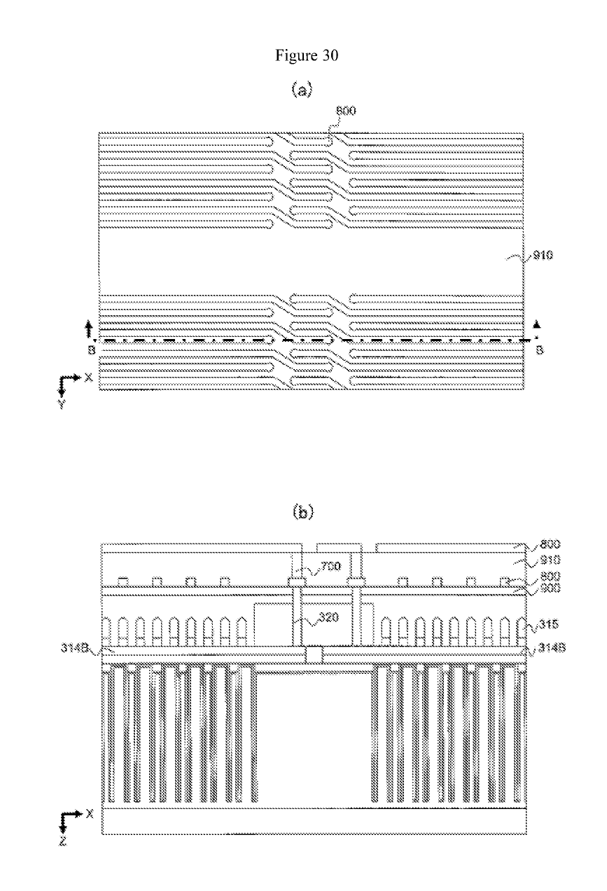

Next, as illustrated in FIGS. 30 (a) and (b), an interlayer insulating film 910 is deposited over the entire surface of the memory semiconductor substrate, contact plugs 700 connected to the wiring lines 800 are formed penetrating through the interlayer insulating film 910, and second wiring lines 800 are formed connected to the upper surfaces of the contact plugs 700.

Next, the protective insulating film 920 illustrated in FIG. 26 is deposited over the entire surface of the memory semiconductor substrate, and memory chip connection terminals 510 connected to the wiring lines 800 are formed penetrating through the protective insulating film 920, thereby completing the memory semiconductor substrate illustrated in FIG. 26.

### Fifth Mode of Embodiment of the Present Invention

A fifth mode embodiment of the present invention will now be described.

A DRAM, which is a semiconductor device, comprises a memory cell region having a capacitor structure, and a peripheral circuit region comprising CMOS circuits. With the progress of miniaturization, differences have arisen in the manufacturing processes for the respective regions, and thus if the regions are manufactured on the same wafer, there are problems in that semiconductor process constraints cause a deterioration in their respective performances, and the manufacturing cost also increases.

Accordingly, in the abovementioned first mode of embodiment, a memory semiconductor substrate on which a plurality of semiconductor memory chips having only a memory cell region are disposed lengthwise and crosswise, and a CMOS semiconductor substrate on which a plurality of semiconductor CMOS chips, having sense amplifier circuit regions, word line drive regions, peripheral circuit regions and silicon through-electrodes, are disposed lengthwise and crosswise, are manufactured using separate manufacturing processes. However, the wiring lines from the memory cells to the sense amplifiers are long and are liable to affected by noise.

The fifth mode of embodiment of the present invention provides, as an improved example of the first mode of embodiment, a semiconductor device with which the effects of noise can be reduced. A 4F2-structure employing vertical transistors is adopted as the memory cell layout of the memory semiconductor substrate, and the bit lines and the word lines are led out to the reverse surface of the memory semiconductor substrate by way of bit line connection terminals and word line connection terminals, and are electrically connected by way of contact plugs and wiring lines to connection terminals exposed at the reverse surface of the memory semiconductor substrate. Now, a bit line leader line and a bit line leader line from an adjacent bank are output as a pair.

In other words, in the fourth mode of embodiment, the connection terminals are led out to the reverse surface side of the memory semiconductor chip, but in the fifth mode of embodiment, in addition to leading the connection terminals out to the reverse surface side, the transistors are formed as fully-depleted vertical transistors, avoiding a floating body and improving the transistor characteristics. The bit lines are formed further toward the reverse surface side than the vertical gates. The distance from the bit lines and the word lines to the connection terminals is reduced, and the bit line capacitance is reduced, thereby also providing the merit that the device is less susceptible to the effects of noise, in the same way as in the fourth mode of embodiment.

The memory cell region and the peripheral circuit regions can thus be formed separately, and therefore the fifth mode of embodiment of the present invention is not susceptible to semiconductor process constraints. Manufacturing costs can also be suppressed. Further, the distance from the bit lines and the word lines to the connection terminals is reduced and the bit line capacitance is reduced, thereby making the device less susceptible to the effects of noise. The transistors are formed as fully-depleted vertical transistors, avoiding a floating body and improving the transistor characteristics.

The fifth mode of embodiment of the present invention will now be described in detail with reference to the drawings.

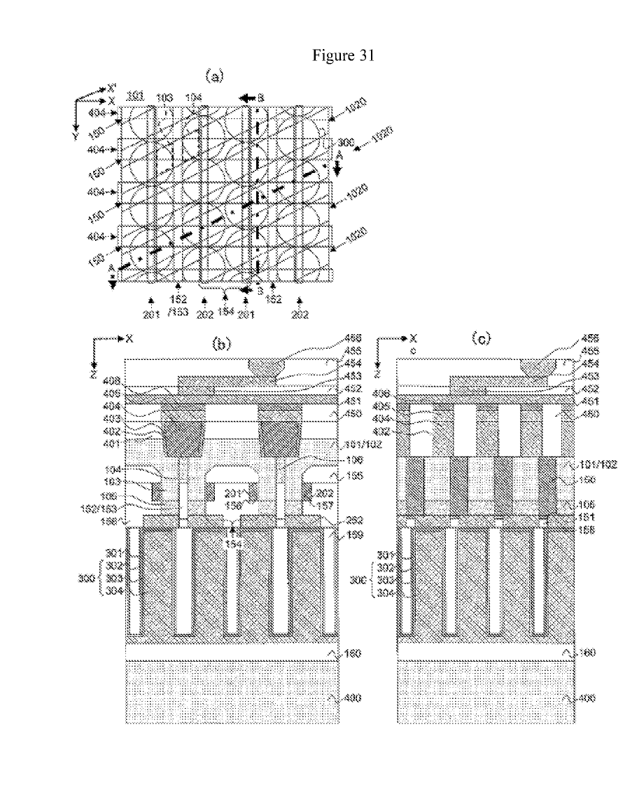

The structure of the 4F2-structure memory cell semiconductor substrate in this mode of embodiment will first be described with reference to FIG. 31.

FIG. 31 (a) is a plan view illustrating the arrangement of the main parts of the memory cell semiconductor substrate. In order to describe the arrangement, only the outline of the main parts is depicted. FIG. 31 (b) is a cross-sectional view along A-A in FIG. 31 (a). FIG. 31 (c) is a cross-sectional view along B-B in FIG. 31 (a).

First, referring to FIG. 31 (a), active regions 1020 are disposed by demarcating the obverse surface side of a memory semiconductor substrate 101 in a repeating manner using STIs (Shallow Trench Insulators) 150 extending in the X′-direction, which is inclined from the X-direction.

Pillar isolation grooves 152 which are narrow in the X-direction, and word trenches 154 which are wide in the X-direction are disposed in a repeating manner, extending in the Y-direction. Parts of the obverse surface sides of the active regions 102 are thus demarcated into a first semiconductor pillar 103 and a second semiconductor pillar 104.

The pillar isolation groove 152 is filled by a pillar isolation insulating film 153, and a first word line 201 in contact with the first semiconductor pillar 103, with the interposition of a first gate insulating film 156 which is not shown in the drawings, is disposed on one of the side surfaces of the word trench 154, and a second word line 202 in contact with the second semiconductor pillar 104, with the interposition of a second gate insulating film 157 which is not shown in the drawings, is disposed on the other side surface of the word trench 154.

Capacitative contact plugs 252, which are not shown in the drawings, are disposed in such a way as to be electrically connected to each of the first semiconductor pillars 103 and second semiconductor pillars 104, and capacitors 300, the detailed structure of which is omitted, are arranged in such a way as to be electrically connected to the capacitative contact plugs 252.

Bit lines 405 are disposed on the reverse surface side of the memory semiconductor substrate 101 in such a way as to connect the active regions 102 between the plurality of first semiconductor pillars 103 and second semiconductor pillars 104 aligned in the X-direction. In other words, bit lines 405 extending in the X-direction are disposed in a repeating manner in the Y-direction.

Next, referring to FIGS. 31 (b) and 31 (c), the Z-direction is the obverse surface side of the memory semiconductor substrate 101, and the −Z-direction is the reverse surface side of the memory semiconductor substrate 101. Active regions 102 are disposed by demarcating the obverse surface side of the memory semiconductor substrate 101 in a repeating manner using the STIs 150 (having a depth of 200 nm, for example). Source/drain diffusion layers 105 are disposed on the obverse surface side of the active regions 102.

Next, by etching using a masking film 151 as a mask, pillar isolation grooves 152 (having a width of 10 nm and a depth of 100 nm, for example) which are narrow in the X-direction and extend in the Y-direction, and word trenches 154 (having a width of 40 nm and a depth of 150 nm, for example) which are wide in the X-direction and extend in the Y-direction, are disposed in a repeating manner. Parts of the obverse surface sides of the active regions 102 are thus demarcated into a first semiconductor pillar 103 and a second semiconductor pillar 104. Further, bit contact diffusion layers 106 are established in a zone from the bottom of the pillar isolation groove 152 to a depth that exceeds the depth of the STI 150.

The pillar isolation groove 152 is filled by a pillar isolation insulating film 153, an embedded insulating film 155 is disposed in the bottom portion of the word trench 154 in such a way as to be coplanar with the bottom of the pillar isolation groove 152, a first word line 201 in contact with the first semiconductor pillar 103, with the interposition of a first gate insulating film 156, is disposed on one of the side surfaces of the word trench 154, on the side of the insulating film 155 that is further toward the obverse surface of the memory cell semiconductor substrate, and a second word line 202 in contact with the second semiconductor pillar 104, with the interposition of a second gate insulating film 157, is disposed on the other side surface of the word trench 154.

The sides of the first word line 201 and the second word line 202 that are further toward the obverse surface of the memory cell semiconductor substrate are coplanar with the sides of the source/drain diffusion layers 105 that are further toward the reverse surface of the memory cell semiconductor substrate. A first interlayer insulating film 158 is disposed over the entire surface, on the obverse surface side, of the memory cell semiconductor substrate 101, in such a way as to fill the remaining portions of the word trenches 154, and capacitative contact plugs 252 connected to the sides of the first semiconductor pillars 103 and the second semiconductor pillars 104 that are further toward the obverse surface side of the memory cell semiconductor substrate are disposed penetrating through the first interlayer insulating film 158.

A second interlayer insulating film 159 is disposed over the entire surface, on the obverse surface side, of the memory cell semiconductor substrate 101, capacitative cylinder holes 301 connected to the sides of the capacitative contact plugs 252 that are further toward the obverse surface side of the memory cell semiconductor substrate are disposed penetrating through the second interlayer insulating film 159, and capacitors 300 comprising a lower electrode 302, a capacitative insulating film 303 and an upper electrode 304 are disposed using the bottom and the side surfaces of the capacitative contact holes 301.

It should be noted that in this mode of embodiment the capacitors 300 are described has having a cylindrical shape, but they may also have other shapes such as crown shapes. A first protective insulating film 160 is disposed over the entire surface, on the obverse surface side, of the memory semiconductor substrate 101 in such a way as to cover the capacitative cylinder holes 301, and a retaining substrate 400 is bonded thereto. The retaining substrate may be anything that is capable of withstanding the manufacturing process, for example a silicon semiconductor substrate or an insulating substrate.

The reverse surface side of the memory semiconductor substrate 101 is ground (until the thickness of the memory semiconductor substrate 101 is 250 nm, for example), and a third interlayer insulating film 401 is disposed over the entire reverse surface of the memory semiconductor substrate 101. Bit contact trenches 402 penetrating through the third interlayer insulating film 401 and the memory semiconductor substrate 101 to reach the bit contact diffusion layers 106 are disposed in a repeating manner in the X-direction, extending in the Y-direction. A liner film 403 is disposed in such a way as to cover the side surfaces of the bit contact trenches 402.

W-bit lines 405 are disposed in such a way as to be connected, by way of phosphorus-doped polysilicon contacts 404, to the plurality of bit contact diffusion layers 106 that are aligned in the X-direction. In other words, bit lines 405 extending in the X-direction are disposed in a repeating manner in the Y-direction. A covering film 406 is disposed on the side of the bit lines 405 that is further toward the reverse surface of the memory cell semiconductor substrate.

A fourth interlayer insulating film 450 is disposed between the bit lines 405 covered by the covering film 406. First wiring lines 451 and a fifth interlayer insulating film 452 are disposed on the side of the fourth interlayer insulating film 450 and the covering film 406 that is further toward the reverse surface of the memory cell semiconductor substrate. It should be noted that parts of the first word lines 451 that are not shown in the drawings are connected by way of contact plugs to bit lines 405, first word lines 201 or second word lines 202. Contact plugs 453 are disposed penetrating through the fifth interlayer insulating film 452 in such a way as to be connected to the first wiring lines 451, second wiring lines 454 are disposed in such a way as to be connected to the side of the contact plugs 453 that is further toward the reverse surface of the memory cell semiconductor substrate, and a second protective insulating film 455 is disposed thereon. Connection terminals 456 are disposed penetrating through the second protective insulating film 455 in such a way as to be connected to the second wiring lines 454.

In this way, by forming the bit lines 405 and the connection terminals 456 on the reverse surface side of the memory cell semiconductor substrate, the connection terminals 456 can be connected to the bit lines 405, the first word lines 201 or the second word lines 202 by a short path, without the memory cells being formed as a floating body, and the device is therefore less susceptible to the effects of noise.

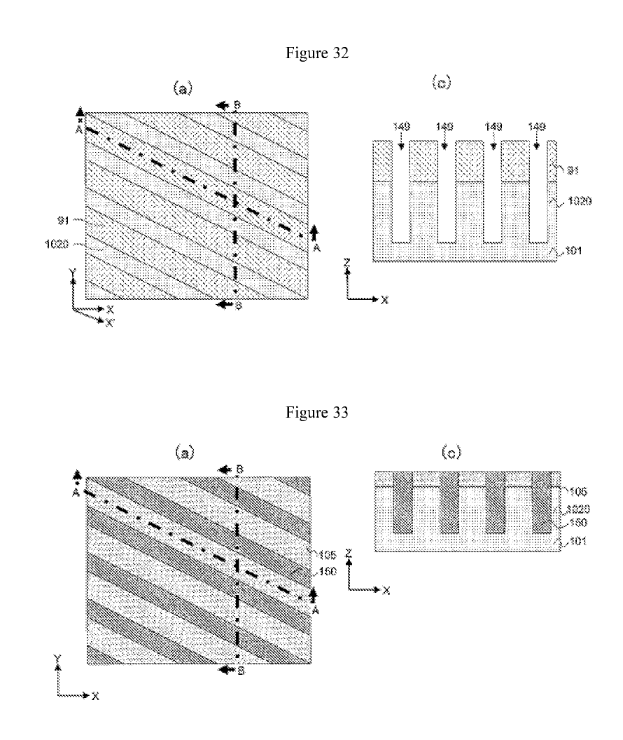

A method of manufacturing the memory semiconductor substrate in this mode of embodiment will now be described with reference to FIG. 32 to FIG. 45. Here, in each drawing, (a) is a plan view of a memory cell part, (b) is a cross-sectional view along A-A in (a), and (c) is a cross-sectional view along B-B in (a).

First, as illustrated in FIG. 32 a resist 91 is applied over the entire obverse surface of a memory semiconductor substrate 101, and shallow trenches 149 (having a width of 20 nm, for example) extending in the X′-direction, which is inclined from the X-direction, are formed using lithography and dry etching.

The obverse surface side of the memory semiconductor substrate 101 is thus demarcated into active regions 102. It should be noted that although a resist 91 mask is described, a laminated masking film for double patterning or the like may also be used.

Next, as illustrated in FIG. 33, the shallow trenches 149 are filled by an insulating film to form STIs. An impurity having the opposite characteristic to the memory semiconductor substrate 101 is next implanted by ion implantation, to form source/drain diffusion layers 105 on the side of the active regions 102 that is further toward the obverse surface of the memory semiconductor substrate 101.

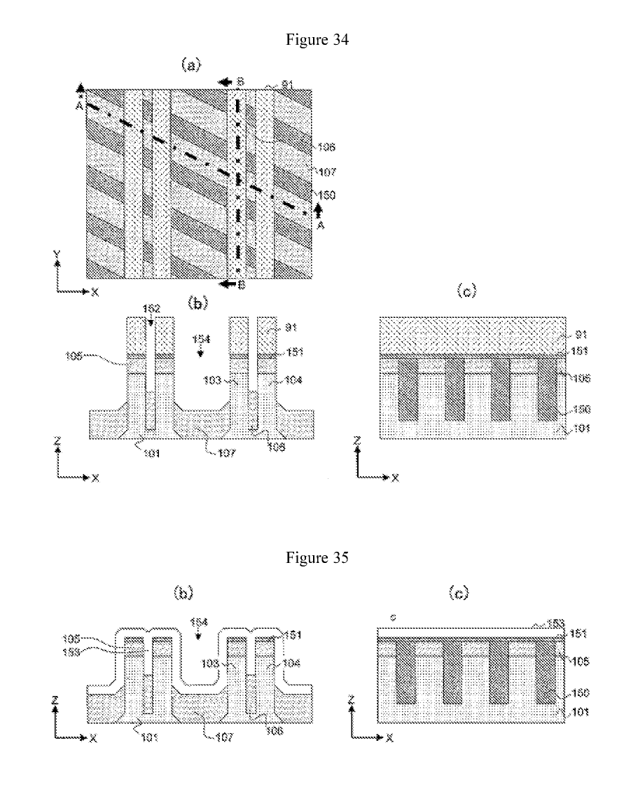

Next, as illustrated in FIG. 34, a masking film 151 is deposited over the entire obverse surface of the memory semiconductor substrate 101, after which a resist 91 is applied, and pillar isolation grooves 152 and word trenches 154 extending in the Y-direction are formed by lithography and dry etching.

The pillar isolation grooves 152 and the word trenches 154 are arranged alternately side-by-side, and the remaining portions form first semiconductor pillars 103 and second semiconductor pillars. It should be noted that although a resist 91 mask is described, it is also possible to use amorphous silicon, or to employ double patterning using a laminated masking film.

Next, using the masking film 151 and the resist 91 as a mask, an impurity having the opposite characteristic to the memory semiconductor substrate 101 is introduced by ion implantation, to form bit contact diffusion layers 106 in a zone from the bottom of the pillar isolation grooves 152 to a depth that exceeds the depth of the STIs 150, and to form sacrificial diffusion layers 107 in a zone from the bottom of the word trenches 154 to a depth that exceeds the depth of the STIs 150.

Next, as illustrated in FIG. 35, a pillar isolation insulating film 153 is deposited over the entire obverse surface of the memory semiconductor substrate 101, including the pillar isolation grooves 152 and the word trenches 154. The thickness of the pillar isolation insulating film 153 is a thickness (6 nm, for example) that completely fills the pillar isolation grooves 152.

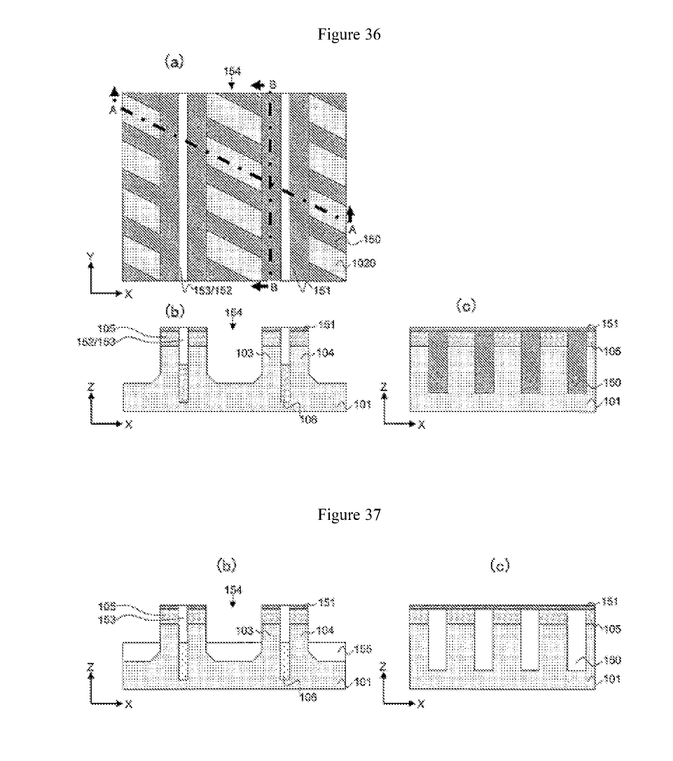

Next, as illustrated in FIG. 36, the pillar isolation insulating film 153 is etched by etch-back or by HF-type oxide film wet-etching, such that the pillar isolation insulating film 153 only remains in the pillar isolation grooves 152.

Next, using the masking film 151 and the pillar isolation insulating film 153 as a mask, an impurity having the same characteristic as the memory semiconductor substrate 101 is introduced by ion implantation, counteracting the sacrificial diffusion layer 107 in the bottom of the word trenches 154 and returning them to the characteristic of the memory semiconductor substrate 101.

Next, as illustrated in FIG. 37, an embedded insulating film 155 is deposited over the entire obverse surface of the memory semiconductor substrate 101 including the insides of the word trenches 154, after which the embedded insulating film 155 is recessed by etching-back, to leave the embedded insulating film 155 in the bottom portions of the word trenches 154, coplanar with the side of the pillar isolation insulating film 153 that is further toward the reverse surface of the memory semiconductor substrate 101.

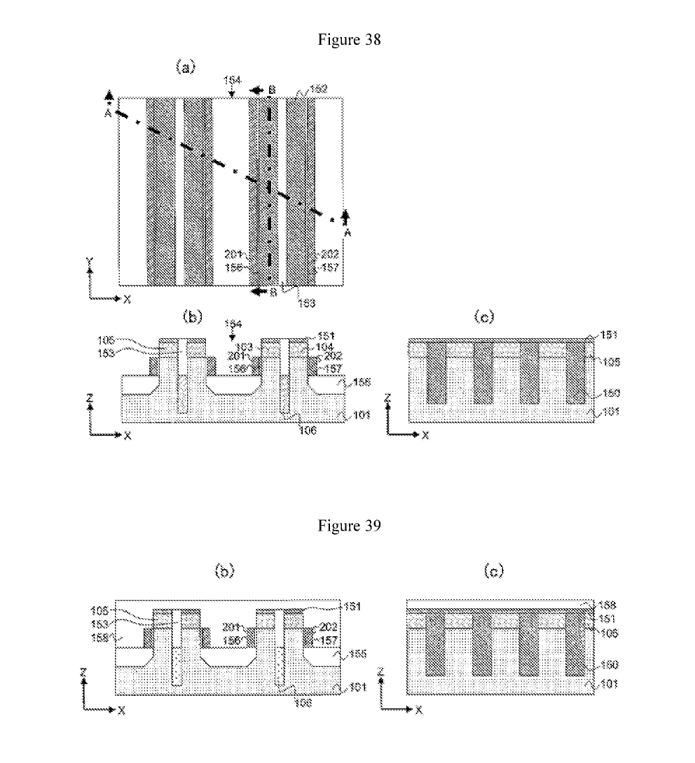

Next, as illustrated in FIG. 38, the side surfaces remaining inside the word trenches 154 are oxidized to form thin first gate insulating films 156 (3 nm, for example) on the side surfaces of the first semiconductor pillars 103, and thin second gate insulating films 157 (3 nm, for example) on the side surfaces of the second semiconductor pillars 104, tungsten is deposited thinly (10 nm, for example) over the entire obverse surface of the memory semiconductor substrate 101, and etch-back is performed, to form first word lines 201 on the side surfaces of the first semiconductor pillars 103 and second word lines 202 on the side surfaces of the second semiconductor pillars 104.

The sides of the first word line 201 and the second word line 202 that are further toward the obverse surface of the memory semiconductor substrate 101 are coplanar with the sides of the source/drain diffusion layers 105 that are further toward the reverse surface of the memory semiconductor substrate 101. In other words, the first word lines 201 are in contact with the side surfaces of the first semiconductor pillars 103, with the interposition of the first gate insulating film 156, and the second word lines 202 are in contact with the side surfaces of the first semiconductor pillars 103, with the interposition of the second gate insulating film 156. The first word lines 201 and the second word lines 202 form the gate electrodes of vertical transistors. Here, the first word lines 201 and the second word lines 202 are formed from tungsten, but another metal or a composite metal material may also be used.

Next, as illustrated in FIG. 39, a first interlayer insulating film 158 is deposited over the entire obverse surface of the memory semiconductor substrate 101, including the remaining insides of the word trenches 154.

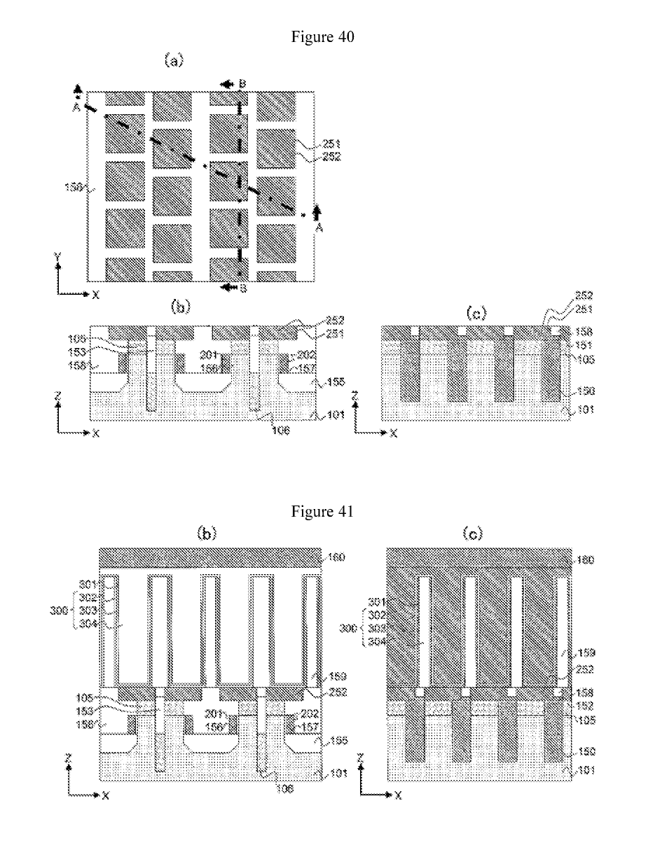

Next, as illustrated in FIG. 40, capacitative contact holes 251 that reach the source/drain diffusion layers 105 are formed by lithography and dry etching, penetrating through the first interlayer insulating film and the masking film 151, and capacitative contact plugs 252 are formed by filling the capacitative contact holes 251 with tungsten. Here, the capacitative contact plugs 252 are formed from tungsten, but another metal, a composite metal material or polysilicon may also be used.

Next, as illustrated in FIG. 41, a thick (1.8 μm, for example) second interlayer insulating film 159 is deposited and is etched using lithography and dry etching until the capacitative contact plugs 252 appear, thereby forming capacitative cylinder holes 301. Here, the capacitative cylinder holes 301 are arranged in a hexagonal close-packed arrangement, but other arrangement methods may also be used. Lower electrodes 302, capacitative insulating films 303 and upper electrodes 304 are then formed in the capacitative cylinder holes 301 to form capacitors 300. A first protective insulating film 160 is then deposited over the entire obverse surface of the memory semiconductor substrate 101.

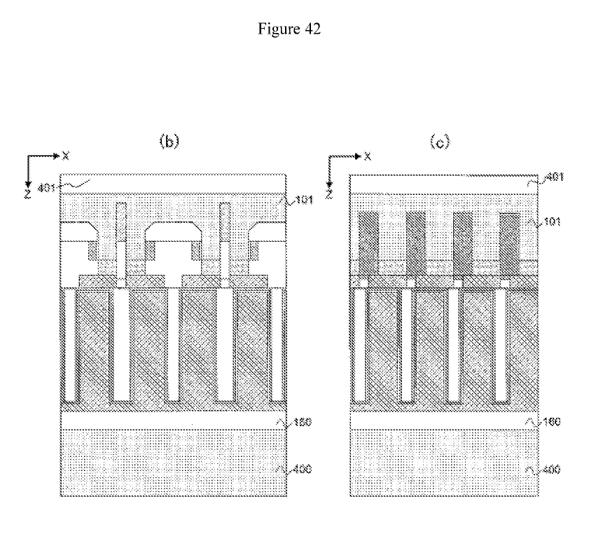

Next, as illustrated in FIG. 42, a retaining substrate 400 is affixed to the obverse surface of the memory semiconductor substrate 101 which is then turned upside down, and the reverse surface of the memory semiconductor substrate 101 is ground (until the thickness of the memory semiconductor substrate 101 is 250 nm, for example). A third interlayer insulating film 401 is then deposited over the entire reverse surface of the memory semiconductor substrate 101.

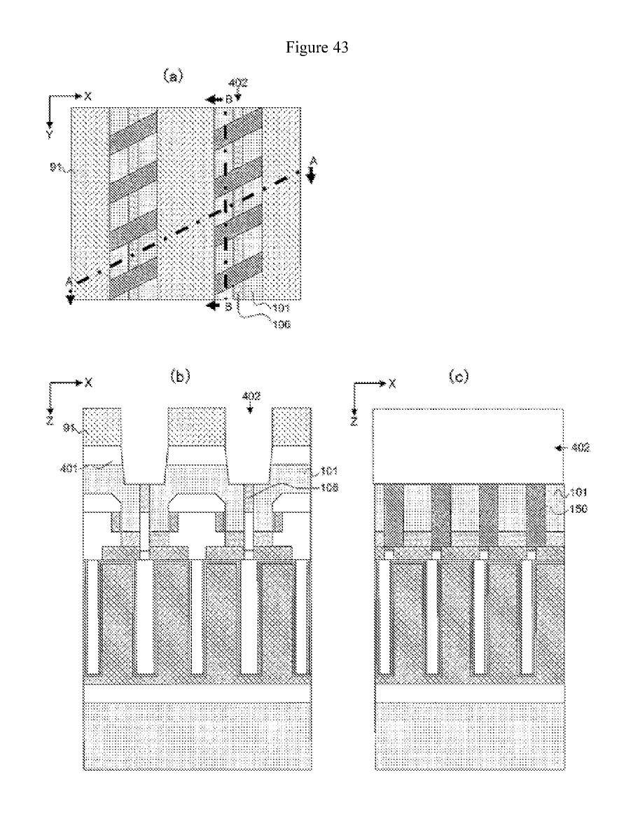

Next, as illustrated in FIG. 43 a resist 91 is applied over the entire reverse surface of the memory semiconductor substrate 101 and etching is performed, using lithography and dry etching, until the bit contact diffusion layers 106 appear, thereby forming bit contact trenches 402. It should be noted that although a resist 91 mask is described, a laminated masking film for double patterning or the like may also be used.

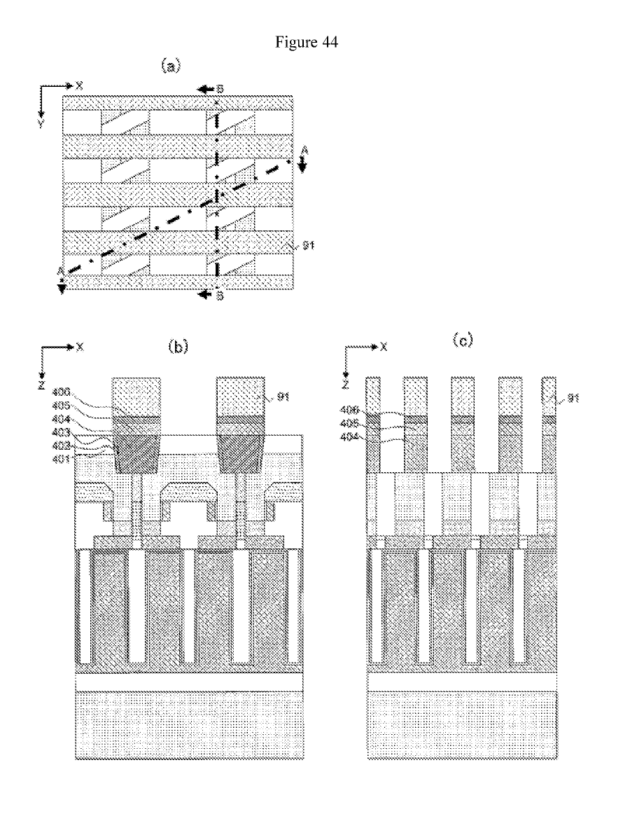

Next, as illustrated in FIG. 44, a silicon nitride film is deposited over the entire reverse surface of the memory semiconductor substrate 101 and is etched back to leave the silicon nitride film on only the side surfaces of the bit contact trenches 402, thereby forming liner films 403. A phosphorus-doped silicon film is then deposited in such a way as to fill the remainder of the bit contact trenches 402, and this is etched back to the surface of the third interlayer insulating film 401 to form phosphorus-doped silicon contacts 404.

A laminated metal film (for example a titanium film with a tungsten film thereon) and a silicon nitride film are then deposited successively over the entire reverse surface of the memory semiconductor substrate 101, a resist 91 is applied, and then bit lines 405 and covering films 406 are formed by lithography and dry etching. It should be noted that although a resist 91 mask is described, a laminated masking film for double patterning or the like may also be used.

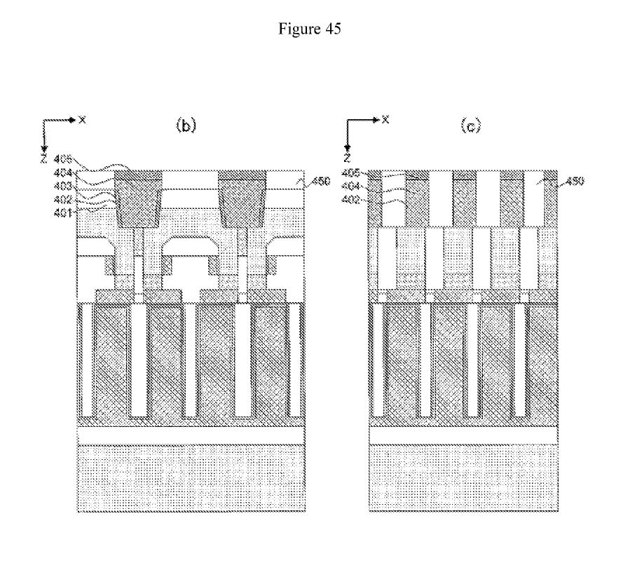

Next, as illustrated in FIG. 45, a fourth interlayer insulating film is deposited, by CVD or SOD, between the bit lines 405 and the covering films 406, including the remaining parts of the bit contact trenches 402, and planarization is performed by CMP, using the cover insulating film as a stop film.

Next, using known methods, first wiring lines 451 and a fifth interlayer insulating film 452 are formed on the side of the fourth interlayer insulating film 450 and the covering film 406 that is further toward the reverse surface of the memory cell semiconductor substrate, contact plugs 453 are formed penetrating through the penetrating through the fifth interlayer insulating film 452 in such a way as to be connected to the first wiring lines 451, second wiring lines 454 are formed in such a way as to be connected to the side of the contact plugs 453 that is further toward the reverse surface of the memory cell semiconductor substrate, and a second protective insulating film 455 is disposed thereon, and connection terminals 456 are formed penetrating through the second protective insulating film 455 in such a way as to be connected to the second wiring lines 454, thereby completing the memory cell semiconductor substrate 101 in FIG. 31.

### Sixth Mode of Embodiment of the Present Invention

A memory semiconductor substrate in a sixth mode of embodiment of the present invention will now be described.

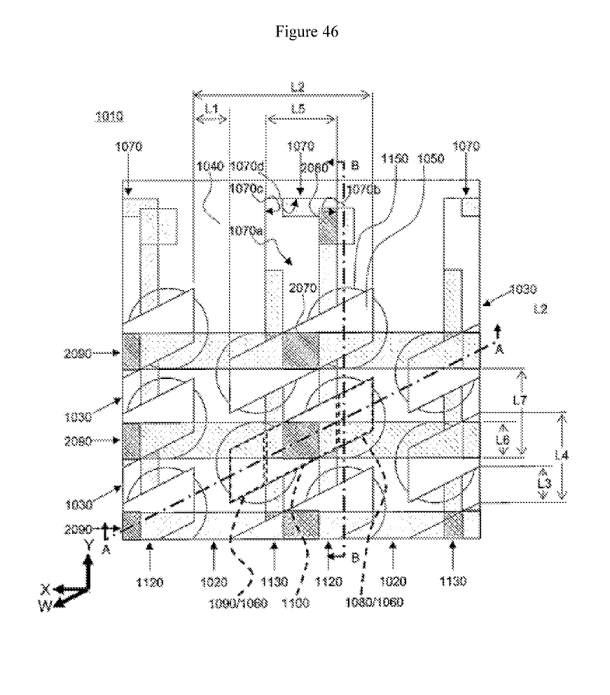

The planar arrangement as far as the bit lines in the sixth mode of embodiment of the present invention will now be described with reference to FIG. 46. FIG. 46 is an enlarged plan view of the edge part of a region in which memory cells are disposed in a memory cell semiconductor substrate 1010 (this is a drawing as seen from above after the memory cell semiconductor substrate has been turned upside down for lamination, and the diffusion layers are drawn sloping diagonally up to the right. Intermediate drawings illustrate the condition before the memory cell semiconductor substrate has been turned upside down, and the diffusion layers are therefore drawn sloping diagonally down to the right).

First element isolation grooves 1020 extending in a second direction Y and having a width L1 are disposed in a repeating manner with a pitch L2 in a first direction X. Second element isolation grooves 1030 extending in a third direction W, which is inclined from the first direction X, and having a width L3 are disposed in a repeating manner with a pitch L4 in the second direction Y. It should be noted that the part at the edge of the region in which the memory cells are disposed is a large region in which the first element isolation grooves 1020 and the second element isolation grooves 1030 are connected.

Element isolation regions 1040 are then disposed in such a way as to fill the first element isolation grooves 1020 and the second element isolation grooves 1030. Here, diffusion layers in the memory semiconductor substrate 1010 form active regions 1050 demarcated by the element isolation regions 1040.

Capacitative diffusion layers 1060 are then disposed on the sides of the active regions 1050 that are further toward the obverse surface of the memory semiconductor substrate 1010. Word grooves 1070 extending in the second direction Y and having a width L5 are then disposed in a repeating manner in the first direction X in such a way as to penetrate through the centers of the element isolation regions 1040 that are aligned in the second direction Y. Here, each word groove 1070 comprises a bottom 1070a, a first wall surface 1070b and a second wall surface 1070c that face each other in the first direction X, and a third wall surface 1070d and a fourth wall surface 1070e (which is not shown in the drawing) that face each other in the second direction Y. Further, the sides of the active regions 1050 that are further toward the obverse surface of the memory semiconductor substrate 1010 are divided into two by the word grooves 1070 to form first semiconductor pillars 1080 and second semiconductor pillars 1090.

Bit diffusion layers 1100 are then disposed in the parts of the active regions 1050 that are in contact with the bottoms 1070a of the word grooves 1070. First cell gate electrodes 1120 are then disposed along the first wall surfaces 1070b and the third wall surfaces 1070d of the word grooves 1070. It should be noted that the part of the first cell gate electrode 1120 that is in contact with the first semiconductor pillar 1080 is insulated using a cell gate insulating film, which is not shown in the drawing.

Second cell gate electrodes 1130 are then disposed along the second wall surfaces 1070c and the fourth wall surfaces 1070e (which are not shown in the drawing) of the word grooves 1070. It should be noted that the part of the second cell gate electrode 1130 that is in contact with the second semiconductor pillar 1090 is insulated using a cell gate insulating film (which is not shown in the drawing).

Capacitative elements 1150 are then disposed on the sides of the first semiconductor pillars 1080 and the second semiconductor pillars 1090 that are further toward the obverse surface of the memory semiconductor substrate 1010. Bit contact plugs 2070 are then disposed on the sides of the bit diffusion layers 1100 that are further toward the reverse surface of the memory semiconductor substrate 1010. Word contact plugs 2080 are then disposed on the first cell gate electrodes 1120 that project out at the edge of the region in which memory cells are disposed, said word contact plugs 2080 being disposed on the sides of the first cell gate electrodes 1120 that are further toward the reverse surface of the memory cell semiconductor substrate 1010.

It should be noted that, although not shown in the drawing, word contact plugs 2080 are also disposed on the second cell gate electrodes 1130 that project out at the opposite edge of the region in which memory cells are disposed, said word contact plugs 2080 being disposed on the sides of the second cell gate electrodes 1130 that are further toward the reverse surface of the memory cell semiconductor substrate 1010. Bit lines 2090 extending in the first direction X and having a width L6 are then disposed in a repeating manner with a pitch L7 in the second direction Y, in such a way as to be connected to the bit contact plugs 2070 that are aligned in the first direction X.

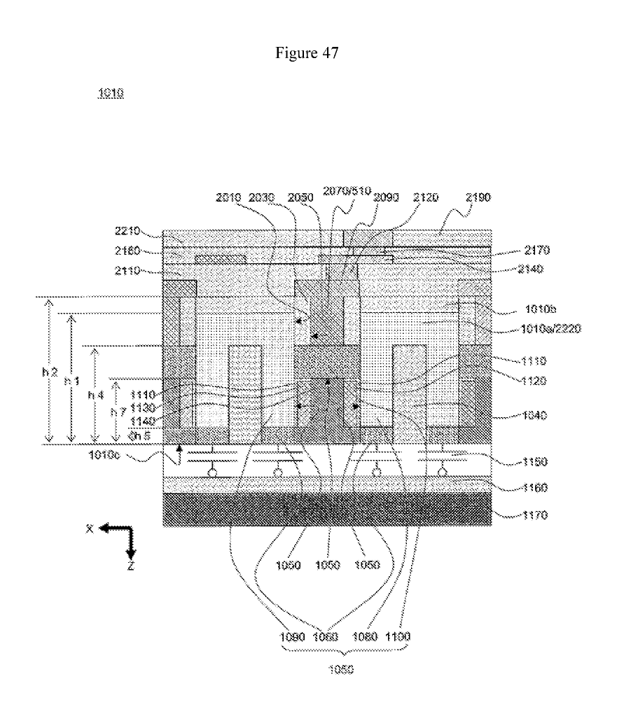

FIG. 47 is a cross-sectional view in which a cross-section along A-A in FIG. 46 is projected onto a vertical plane extending in the first direction X.

A box layer 1010b is disposed in a zone from a depth h1 to a depth h2 from the obverse surface 1010c of the memory semiconductor substrate 1010. The element isolation regions 1040 are disposed from the obverse surface 1010c of the memory semiconductor substrate 1010 to a depth h4, as illustrated in FIG. 46. The memory semiconductor substrate 1010 is thus demarcated from its obverse surface 1010c to a depth h4, forming the active regions 1050.

Further, the capacitative diffusion layers 1060 are disposed in the active regions 1050, from the obverse surface 1010c of the memory semiconductor substrate 1010 to a depth h5. The word grooves 1070 are then disposed from the obverse surface 1010c of the memory semiconductor substrate 1010 to a depth h7, as illustrated in FIG. 46. The active regions 1050, from the obverse surface 1010c of the memory semiconductor substrate 1010 to a depth h7, are thus divided into the first semiconductor pillars 1080 and the second semiconductor pillars 1090.

Further, the bit diffusion layers 1100 are disposed in the active regions 1050 corresponding to the bottom 1070a parts of the word grooves 1070, in other words from a depth h7 to a depth h4 as seen from the obverse surface 1010c of the memory semiconductor substrate 1010. In other words, the active regions 1050 comprise the capacitative diffusion layers 1060, the first semiconductor pillars 1080, the second semiconductor pillars 1090 and the bit diffusion layers 1100.

The first cell gate electrodes 1120 are then disposed in a zone from a depth h1 to a depth h2 from the obverse surface 1010c of the memory semiconductor substrate 1010, as illustrated in FIG. 46. It should be noted that the part of the first cell gate electrode 1120 that is in contact with the first semiconductor pillar 1080 is insulated using a cell gate insulating film 1110.

Further, the second cell gate electrodes 1130 are disposed in a zone from a depth h5 to a depth h7 from the obverse surface 1010c of the memory semiconductor substrate 1010, as illustrated in FIG. 46. It should be noted that the part of the second cell gate electrode 1130 that is in contact with the second semiconductor pillar 1090 is insulated using the cell gate insulating film 1110. Further, cap insulating films (insulating films between the gates) 1140 are disposed in such a way as to fill the remainder of the word grooves 1070.

The capacitative elements 1150 are then disposed in such a way as to be connected to the capacitative diffusion layers 1060 of the first semiconductor pillars 1080 and the second semiconductor pillars 1090. It should be noted that the capacitative elements 1150 may have any shape, for example a crown shape, a concave shape or a fin shape. The capacitative elements 1150 are therefore illustrated in the drawing using schematic symbols.

First bit contact grooves 2010 are then disposed penetrating through the box layer 1010b from the reverse side of the memory semiconductor substrate 1010 to a depth that reaches the bit diffusion layers 1100 in the diffusion layers 1010a, as illustrated in FIG. 46. The remaining parts of the diffusion layers 1010a thus form ground regions 2220.

First spacer films 2030 are then disposed on the sidewalls of the first bit contact grooves 2010. The first bit contact grooves 2010 are thus narrowed, forming second bit contact grooves 2050. The bit contact plugs 2070 are then disposed in the second bit contact grooves 2050 in such a way as to be connected to the bit diffusion layers 1100.

The bit lines 2090 are then disposed in such a way as to be connected to the bit contact plugs 2070 that are aligned in the first direction X, as illustrated in FIG. 46. Further, a first interlayer insulating film 2110 is disposed on the box layer 1010b in such a way as to embed the bit lines 2090 and the bit contact plugs 2070.

Bit wiring line contact plugs 2120 are then disposed in such a way as to penetrate through the first interlayer insulating film 2110 and connect to the bit lines 2090. Bit wiring lines 2140 are then disposed on the first interlayer insulating film 2110 in such a way as to be connected to the bit wiring line contact plugs 2120. Further, a second interlayer insulating film 2160 is disposed on the first interlayer insulating film 2110 in such a way as to embed the bit wiring lines 2140.

Bit connection terminal contact plugs 2170 are then disposed in such a way as to penetrate through the second interlayer insulating film 2160 and connect to the bit wiring lines 2140. A third interlayer insulating film 2210 is then disposed on the second interlayer insulating film 2160. Bit connection terminals 2190 are then disposed in such a way as to penetrate through the third interlayer insulating film 2210 and connect to the bit connection terminal contact plugs 2170.

Here, in the fifth mode of embodiment described hereinabove, as illustrated in FIG. 31 and FIGS. 34 to 44, the bit lines 405 are formed in such a way as to be connected by way of the contact plugs 404 to the bit contact diffusion layers 106 formed between the semiconductor pillars 103. The bit contact diffusion layers 106 are formed between the semiconductor pillars 103, and therefore with the layout in the fifth mode of embodiment there is a limit to how wide the space between the pillars can be made.

Accordingly, with the layout in the sixth mode of embodiment of the present invention, by creating diffusion layers connected to the bit lines in the word groove portions, and creating gate electrodes on the sidewalls of the groove portions, the width of the diffusion layers connected to the bit lines can be increased to the width between the gate electrodes. The surface area in contact with the contacts can therefore be increased, increasing the grid alignment margin. With the layout in the sixth mode of embodiment of the present invention, the structure is such that the bit contact diffusion layers are directly below the gate electrodes. Further, with the abovementioned fifth mode of embodiment, ion implantation is required to counteract the sacrificial diffusion layers 107 in the word grooves, as illustrated in FIG. 37, but this process is not required in the sixth mode of embodiment of the present invention.

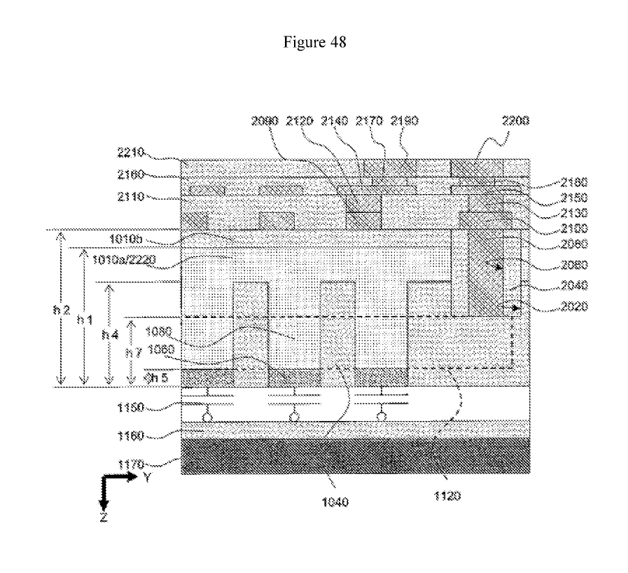

FIG. 48 is a cross-sectional view in which a cross-section along B-B in FIG. 46 is projected onto a vertical plane extending in a second direction Y.

The structure in the vicinity of the word contact plugs 2080 that are not illustrated in FIG. 47 will now be described with reference to FIG. 48.

First word contact holes 2020 are first disposed penetrating through the box layer 1010b and the diffusion layer 1010a from the reverse side of the memory semiconductor substrate 1010 to a depth that reaches the first cell gate electrodes 1120, illustrated by the dashed line, in the element isolation regions 1040. It should be noted that, although not shown in the drawing, first word contact holes 2020 are also disposed at the opposite edge of the region in which memory cells are disposed, to a depth that reaches the second cell gate electrodes 1130.

Second spacer films 2040 are then disposed on the sidewalls of the first word contact holes 2020. The first word contact holes 2020 are thus narrowed, forming second word contact holes 2060. The word contact plugs 2080 are then disposed in the second word contact holes 2060 in such a way as to be connected to the first cell gate electrodes 1120. It should be noted that, although not shown in the drawing, word contact plugs 2080 are also disposed at the opposite edge of the region in which memory cells are disposed, in such a way as to be connected to the second cell gate electrodes 1130.

Word contact pads 2100 are then disposed in such a way as to be connected to the word contact plugs 2080. The first interlayer insulating film 2110 is then disposed on the box layer 1010b in such a way as to embed the word contact pads 2100. Word wiring line contact plugs 2130 are also disposed in such a way as to penetrate through the first interlayer insulating film 2110 and connect to the word contact pads 2100.

Word wiring lines 2150 are then disposed on the first interlayer insulating film 2110 in such a way as to be connected to the word contact pads 2100. Further, the second interlayer insulating film 2160 is disposed on the first interlayer insulating film 2110 in such a way as to embed the word wiring lines 2150. Word connection terminal contact plugs 2180 are then disposed in such a way as to penetrate through the second interlayer insulating film 2160 and connect to the word wiring lines 2150. Further, the third interlayer insulating film 2210 is disposed on the second interlayer insulating film 2160. Word connection terminals 2200 are also disposed in such a way as to penetrate through the third interlayer insulating film 2210 and connect to the word connection terminal contact plugs 2180.

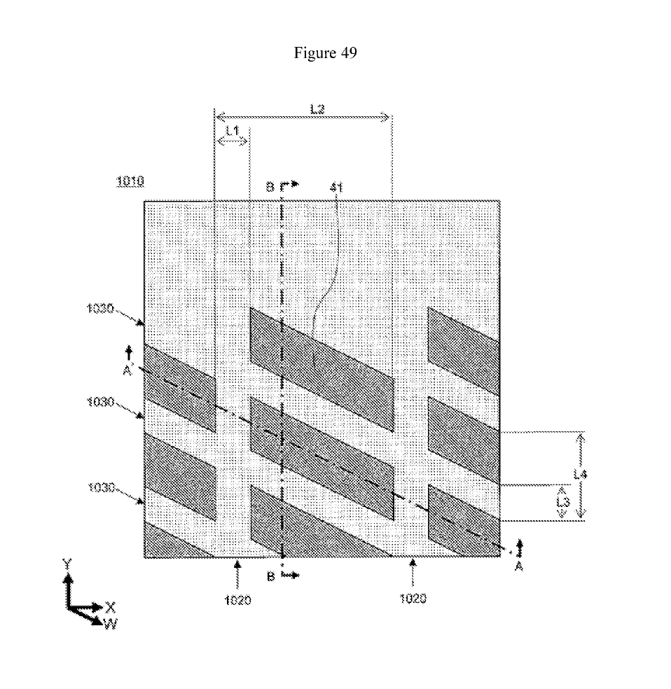

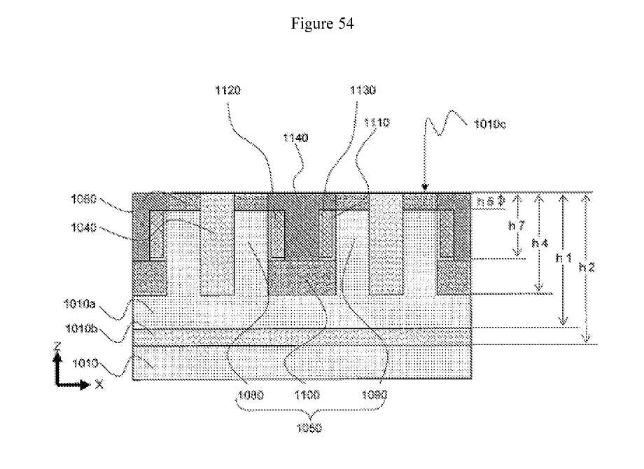

A method of manufacturing the memory semiconductor substrate in the sixth mode of embodiment of the present invention will now be described with reference to FIG. 49 to FIG. 54.

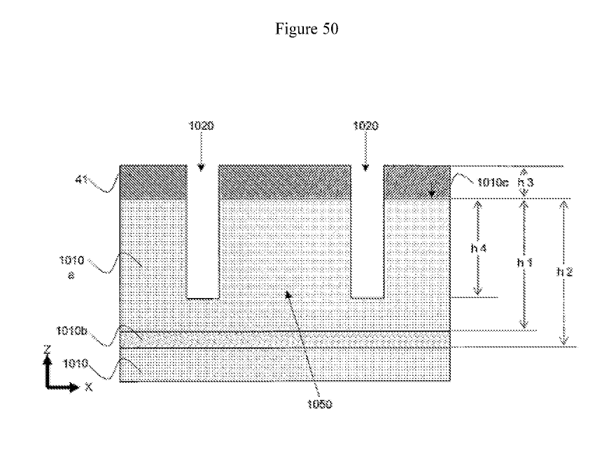

Here, FIG. 49 is a plan view, and FIG. 50 is a cross-sectional view in which a cross-section along A-A in FIG. 49 is projected onto a vertical plane extending in the first direction X.

A memory semiconductor substrate 1010 having an SOI construction is employed, implantation being used to form a box layer 1010b in a zone from a depth h1 to a depth h2 (for example 400 nm to 350 nm) from the obverse surface 1010c of the memory semiconductor substrate 1010. A zone from the obverse surface 1010c of the memory semiconductor substrate 1010 to a depth h1 thus forms an active region 1010a. It should be noted that the box layer 1010b is formed by implantation, but another method may also be used, for example affixing an insulating material and growing silicon on the insulating material.

A silicon nitride film is then deposited to a thickness h3 (50 nm, for example) on the obverse surface of the memory cell semiconductor substrate 1010, and lithography and dry etching are used to form a first masking silicon nitride film 41 in which a pattern part has been removed, where said pattern part comprises a large region in which stripes having a width L1 (20 nm, for example), extending in the second direction Y and being repeated in the first direction X with a pitch L2 (120 nm, for example), and stripes having a width L3 (20 nm, for example), extending in the third direction W, which is inclined from the first direction X, and being repeated in the second direction Y with a pitch L4 (60 nm, for example) are connected to each other, in a part at the edge of a region in which said stripes overlap and in which memory cells are disposed.

The active region 1010a is then etched to a depth h4 (300 nm, for example) from the obverse surface 1010c of the memory semiconductor substrate 1010, by dry etching using the first masking silicon nitride film 41 as a mask. By this means, first element isolation grooves 1020 having a width L1, extending in the second direction Y, and being disposed in a repeated manner in the first direction X with a pitch L2, and second element isolation grooves 1030 having a width L3, extending in the third direction W, which is inclined from the first direction X, and being disposed in a repeated manner in the second direction Y with a pitch L4, are formed. It should be noted that the part at the edge of the region in which the memory cells are disposed is a large region in which the first element isolation grooves 1020 and the second element isolation grooves 1030 are connected.

A silicon dioxide film is then deposited in such a way as to fill the grooves and is planarized by CMP to form element isolation regions 1040.

Capacitative diffusion layers 1060 are then formed by ion implantation to a depth h5 from the surface of the substrate.

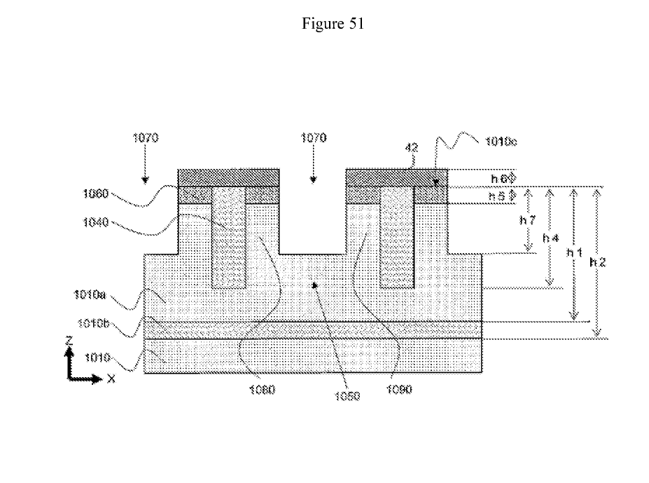

FIG. 51 is a cross-sectional view in which a cross-section along A-A is projected onto a vertical plane extending in the first direction X.

Referring to FIG. 51, a silicon nitride film is deposited on the obverse surface of the memory semiconductor substrate 1010 to a thickness h6 (100 nm, for example), and lithography and dry etching are used to form a second masking silicon nitride film 42 in which a pattern having a width L5 (20 nm, for example) extending across the center of the active region 1050, and extending in the second direction Y, has been removed.

The element isolation regions 1040 and the active region 1050 are then etched to a depth h7 from the obverse surface 1010c of the memory semiconductor substrate 1010, by dry etching using the second masking silicon nitride film 42 as a mask, to form word grooves 1070.

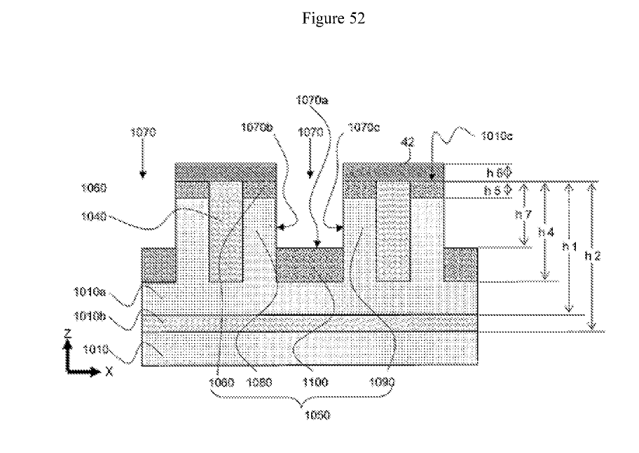

Reference is now made to FIG. 52. FIG. 52 is a cross-sectional view in which a cross-section along A-A is projected onto a vertical plane extending in the first direction X.

Referring to FIG. 52, ion implantation is used to form bit diffusion layers 1100, into which an n-type impurity has been introduced, in the active region 1050 that has appeared at the bottom 1070a of the word grooves 1070, in a zone extending to a depth h4 from the obverse surface 1010c of the memory semiconductor substrate 1010. By this means first semiconductor pillars 1080 and second semiconductor pillars 1090 are formed, said first semiconductor pillars 1080 being in contact, in three directions, with the element isolation regions 1040, and being in contact, in the remaining one direction, with the first wall surfaces 1070b of the word grooves 1070 and the bit diffusion layers 1100, and said second semiconductor pillars 1090 being in contact, in three directions, with the element isolation regions 1040, and being in contact, in the remaining one direction, with the second wall surfaces 1070c of the word grooves 1070 and the bit diffusion layers 1100. In other words, the active regions 1050 comprise the bit diffusion layers 1100, the first semiconductor pillars 1080, the second semiconductor pillars 1090, and the capacitative diffusion layers 1060.

Lamp annealing is then used to form a cell gate insulating film (which is not shown in the drawing) on the surface of the first semiconductor pillar 1080 appearing at the first wall surface 1070b of the word groove 1070, the second semiconductor pillar 1090 appearing at the second wall surface 1070c of the word groove 1070, and the bit diffusion layer 1100 appearing at the bottom 1070a of the word groove 1070.

A method of depositing a titanium nitride film having good covering properties is then used to deposit a titanium nitride film (which is not shown in the drawings) to a thickness h8 (20 nm, for example) onto the obverse surface of the second masking silicon nitride film 42, including the bottom and the sidewalls of the word grooves 1070. The titanium nitride film (which is not shown in the drawings) is then etched back by dry etching to leave the titanium nitride film (which is not shown in the drawings) on only the first sidewalls 1070b, the second sidewalls 1070c and the third sidewalls 1070d of the word grooves 1070.

A silicon nitride film (which is not shown in the drawings) is then deposited over the entire surface of the memory semiconductor substrate 1010 in such a way as to fill the remaining portions of the word grooves 1070.

The silicon nitride film (which is not shown in the drawings) is then removed by CMP or nitride film wet etching until the obverse surfaces of the element isolation regions 1040 and the capacitative diffusion layers 1060 appear. By this means the silicon nitride film (which is not shown in the drawings) forms cap insulating films 1140 remaining only inside the word grooves 1070.

A known method is then used to form capacitative elements 1150 in such a way that they are connected to the capacitative diffusion layers 1060. The capacitative elements 1150 may have any shape, for example a crown shape, a concave shape or a fin shape.

A protective insulating film 1160 is then deposited onto the capacitative elements 1150 by CVD. A support substrate 1170 is then affixed.

The memory semiconductor substrate 1010 is then turned upside down. In the following description, the direction in which the value of Z, in the height direction, decreases is described as upward. The reverse surface is then ground until the box layer 1010b appears.

A silicon nitride film is then deposited onto the box layer 1010b, and a third masking silicon nitride film (which is not shown in the drawings) is then formed. Using the third masking silicon nitride film as a mask, first bit contact grooves 2010 reaching the bit diffusion layers 1050 and first word contact holes 2020 reaching the first cell gate electrodes 1120 are formed.

A silicon dioxide film 30 is then deposited by CVD to a thickness h9 (10 nm, for example). The silicon dioxide film 30 is etched back so that it remains only on the bottoms and the sidewalls of the first bit contact grooves 2010 and the first word contact holes 2020, to form first spacers 2030 in the first bit contact grooves 2010 and second spacers 2040 in the first word contact holes (which are not shown in the drawings).

A phosphorus-doped polysilicon film (which is not shown in the drawings) is then deposited by CVD in such a way as to fill the second bit contact grooves 2050 and the second word contact holes 2060, and is etched back so as to remain only in the second bit contact grooves 2050 and the second word contact holes 2060, to form phosphorus-doped silicon-filled layers 51 (bit contact plugs 2070 for connecting to the bit lines, in the cell portions), and word contact plugs 2080 (plugs for providing an electric potential to the gate electrodes, in the cell portions).

A composite metal film 15 (which is not shown in the drawings) comprising titanium, titanium nitride, tungsten nitride, tungsten or the like is then deposited to a thickness of 20 nm using a sputtering method. Lithography and dry etching are used to form a pattern of bit lines 2090 having a width L6 (20 nm, for example), extending in the first direction X, and being repeated in the second direction Y with a pitch L7 (60 nm, for example), and a pattern of word contact pads 2100 disposed in such a way as to be connected to the word contact plugs 2080, and the composite metal film (which is not shown in the drawings) is etched to form bit lines 2090, bit contact plugs 2070 and word contact pads 2100.

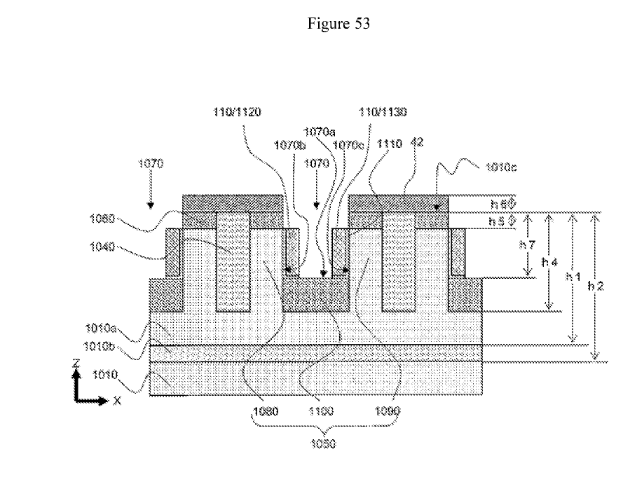

Reference is now made to FIG. 53. FIG. 53 is a cross-sectional view in which a cross-section along A-A is projected onto a vertical plane extending in the first direction X.

The titanium nitride film (which is not shown in the drawings) is etched back by dry etching, to leave the titanium nitride film only on the surfaces of the first sidewalls 1070b, the second sidewalls 1070c, the third sidewalls 1070d and the fourth sidewalls 1070e, which are not shown in the drawings, of the word grooves 1070. In FIG. 53 the cell gate insulating film (which is not shown in the drawings) is also etched back at this time, but it may be left in place.

Lithography and dry etching are then used to remove the parts of the titanium nitride film where the second sidewalls 1070c and the third sidewalls 1070d are in contact, and to remove the parts of the titanium nitride film where the first sidewalls 1070b and the fourth sidewalls 1070e, which are not shown in the drawings, are in contact, thereby making the titanium nitride films 12 on the first gate electrode 1070b side, and the titanium nitride films on the second sidewall 1070c side independent of each other, and forming first cell gate electrodes 1120 and second cell gate electrodes 1130.

Reference is now made to FIG. 47 and FIG. 48. Here, FIG. 47 is a cross-sectional view in which a cross-section along A-A in FIG. 46 is projected onto a vertical plane extending in the first direction X. FIG. 48 is a cross-sectional view in which a cross-section along B-B in FIG. 46 is projected onto a vertical plane extending in a second direction Y.

A silicon nitride film is deposited over the entire surface of the memory semiconductor substrate 1010 in such a way as to fill the remaining portions of the word grooves 1070.

Referring to FIG. 47, the silicon nitride film is then removed by CMP or nitride film wet etching until the obverse surfaces of the element isolation regions 1040 and the capacitative diffusion layers 1060 appear. By this means the silicon nitride film forms cap insulating films 1140 remaining only inside the word grooves 1070.

A known method is then used to form capacitative elements 1150 in such a way that they are connected to the capacitative diffusion layers 1060. The capacitative elements 1150 may have any shape, for example a crown shape, a concave shape or a fin shape.

A protective insulating film 1160 is then deposited onto the capacitative elements 1150 by CVD.

A support substrate 1170 is then affixed using a permanent bonding technique, and the memory semiconductor substrate 1010 is turned upside down. In the following description, the direction in which the value of Z, in the height direction, decreases is described as upward.

The reverse surface is then ground until the box layer 1010b appears. A third masking silicon nitride film 43 is formed. Then, using the third masking silicon nitride film as a mask, first bit contact grooves 2010 reaching the bit diffusion layers 1050 and first word contact holes reaching the first cell gate electrodes 1120 are formed.

The memory semiconductor substrate of the sixth mode of embodiment is then completed by performing a process of forming a first interlayer insulating film 2110, a process of forming bit wiring line contact plugs 2120 and word wiring line contact plugs 2130, a process of forming bit wiring lines 2140 and word wiring lines 2150, a process of forming a second interlayer insulating film 2160, a process of forming bit connection terminal contact plugs 2170 and word connection terminal contact plugs 2180, a process of forming bit connection terminals 2190 and word connection terminals 2200, and a process of forming a third interlayer insulating film 2210. Finally, the memory semiconductor substrate is laminated to a second semiconductor chip.

### Seventh Mode of Embodiment of the Present Invention

A memory semiconductor substrate in a seventh mode of embodiment of the present invention will now be described.

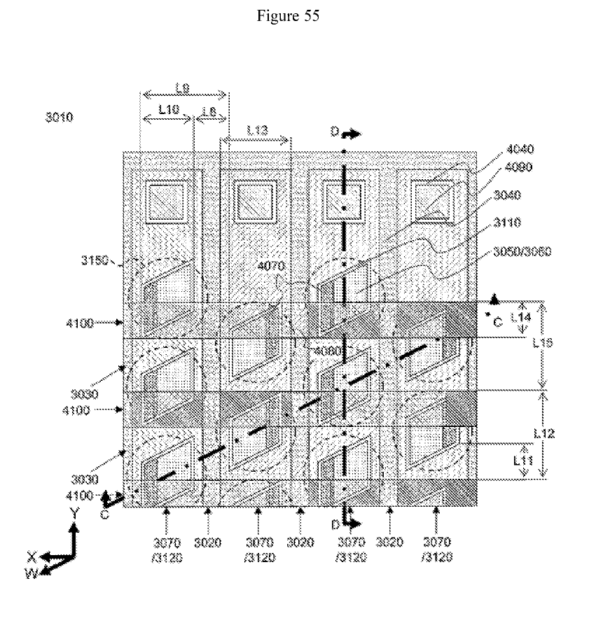

The planar arrangement as far as the bit lines in the seventh mode of embodiment of the present invention will now be described with reference to FIG. 55. FIG. 55 is an enlarged plan view of the edge part of a region in which memory cells are disposed, in a memory cell semiconductor substrate 3010.

First element isolation grooves 3020 extending in a second direction Y and having a width L8 are first disposed in a repeating manner with a pitch L9 in a first direction X. Second element isolation grooves 3030 extending in a third direction W, which is inclined from the first direction X, and having a width L11 are disposed in a repeating manner with a pitch L12 in the second direction Y. It should be noted that the part at the edge of the region in which the memory cells are disposed is a large region in which the first element isolation grooves 3020 and the second element isolation grooves 3030 are connected.

Element isolation regions 3040 are then disposed in such a way as to fill the first element isolation grooves 3020 and the second element isolation grooves 3030. Here, diffusion layers in the memory semiconductor substrate 3010 form active regions 3050 demarcated by the element isolation regions 3040. Capacitative diffusion layers 3060 are then disposed on the sides of the active regions 3050 that are further toward the obverse surface of the memory semiconductor substrate 3010.

Word grooves 3070 extending in the second direction Y and having a width L13 are then disposed in a repeating manner in the first direction X in such a way as to be concentric with the active regions 3050 that are aligned in the second direction Y. At this time, the active regions 3050 remain in the form of pillars in the word grooves 3070.

A cell gate insulating film 3110 is then disposed on the obverse surfaces of the active regions 3050 that remain in the form of pillars in the word grooves 3070. Cell gate electrodes 3120 are then disposed in the word grooves 3070. In other words, the active regions 3050 are surrounded by the cell gate electrodes 3120, with the cell gate insulating films 3110 therebetween.

Capacitative elements 3150 are then disposed on the sides of the capacitative diffusion layers 3060 that are further toward the obverse surface of the memory semiconductor substrate 3010. Bit lines 4100 extending in the first direction X and having a width L14 are then disposed in a repeating manner with a pitch L15 in the second direction Y.

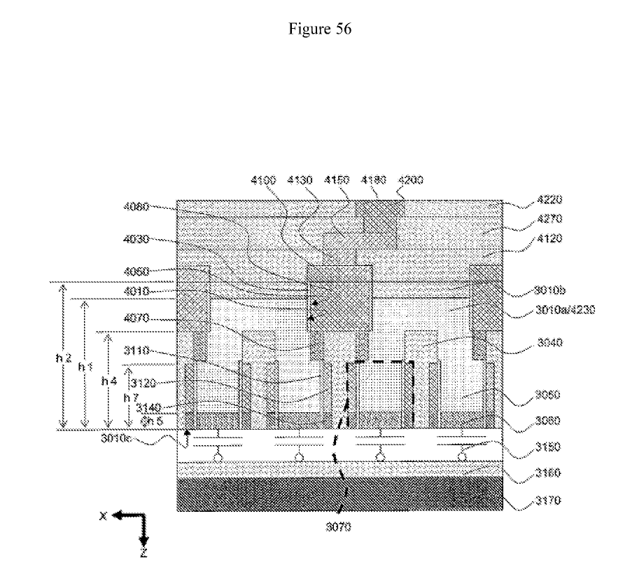

FIG. 56 is a cross-sectional view in which a cross-section along C-C in FIG. 55 is projected onto a vertical plane extending in the first direction X.

A box layer 3010b is first disposed in a zone from a depth h1 to a depth h2 from the obverse surface 3010c of the memory semiconductor substrate 3010. The element isolation regions 3040 are then disposed from the obverse surface 3010c of the memory semiconductor substrate 3010 to a depth h4. The memory semiconductor substrate 3010 is thus demarcated from its obverse surface 3010c to a depth h4, forming the active regions 3050.

The capacitative diffusion layers 3060 are then disposed in the active regions 3050, from the obverse surface 3010c of the memory semiconductor substrate 3010 to a depth h5. The word grooves 3070 are then disposed from the obverse surface 3010c of the memory semiconductor substrate 3010 to a depth h7. By this means, the active regions 3050, from the obverse surface 3010c of the memory semiconductor substrate 3010 to a depth h7, take the form of pillars. The pillar parts of the active regions 3050 are then insulated using cell gate insulating films 3110.

The cell gate electrodes 3120 are then disposed in a zone from a depth h1 to a depth h2 from the obverse surface 3010c of the memory semiconductor substrate 3010, in the word grooves 3070. The cap insulating films 3140 are then disposed in such a way as to fill the remainder of the word grooves 3070. The capacitative elements 3150 are then disposed in such a way as to be connected to the capacitative diffusion layers 3060. It should be noted that the capacitative elements 3150 may have any shape, for example a crown shape, a concave shape or a fin shape. The capacitative elements 1150 are therefore illustrated in the drawing using schematic symbols.

First bit contact grooves 4010 are then disposed penetrating through the box layer 3010b from the reverse side of the memory semiconductor substrate 3010 to a depth that reaches the element isolation regions 3040 in the diffusion layers 3010a. The remaining parts of the diffusion layers 3010a thus form ground regions 4230.

Bit diffusion layers 4070 are then disposed in the active regions 3050, from the bottoms of the first bit contact grooves 4010 to a depth h4 from the obverse surface 3010c of the memory semiconductor substrate 3010. In the seventh mode of embodiment of the present invention, active regions 3050 are formed corresponding to one pillar.

First spacer films 4030 are then disposed on the sidewalls of the first bit contact grooves 4010. The first bit contact grooves 4010 are thus narrowed, forming second bit contact grooves 4050. Bit contact plugs 4080 are then disposed in the second bit contact grooves 4050 in such a way as to be connected to the bit diffusion layers 4070.

Bit lines 4100 are then disposed in such a way as to be connected to the bit contact plugs 4080 that are aligned in the first direction X. A first interlayer insulating film 4120 is then disposed on the box layer 3010b in such a way as to embed the bit lines 4100 and the bit contact plugs 4080.

Bit wiring line contact plugs 4130 are then disposed in such a way as to penetrate through the first interlayer insulating film 4120 and connect to the bit lines 4100. Bit wiring lines 4150 are then disposed on the first interlayer insulating film 4120 in such a way as to be connected to the bit wiring line contact plugs 4130. A second interlayer insulating film is then disposed on the first interlayer insulating film 4120 in such a way as to embed the bit wiring lines 4150.

Bit connection terminal contact plugs 4180 are then disposed in such a way as to penetrate through the second interlayer insulating film and connect to the bit wiring lines 4150. A third interlayer insulating film 4220 is then disposed on the second interlayer insulating film. Bit connection terminals 4200 are then disposed in such a way as to penetrate through the third interlayer insulating film 4220 and connect to the bit connection terminal contact plugs 4180.

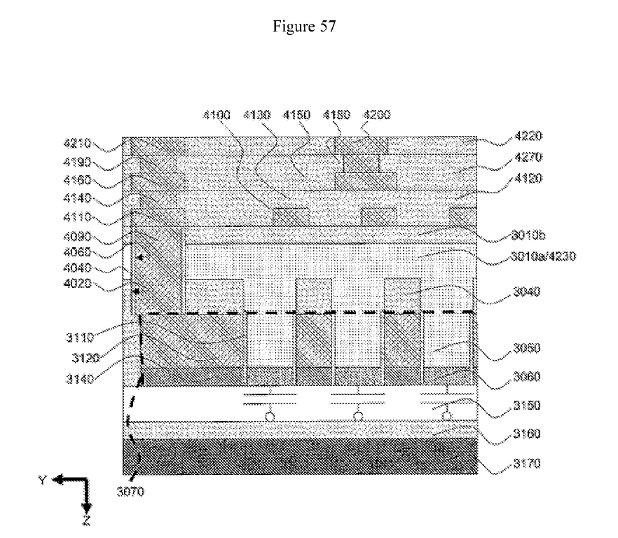

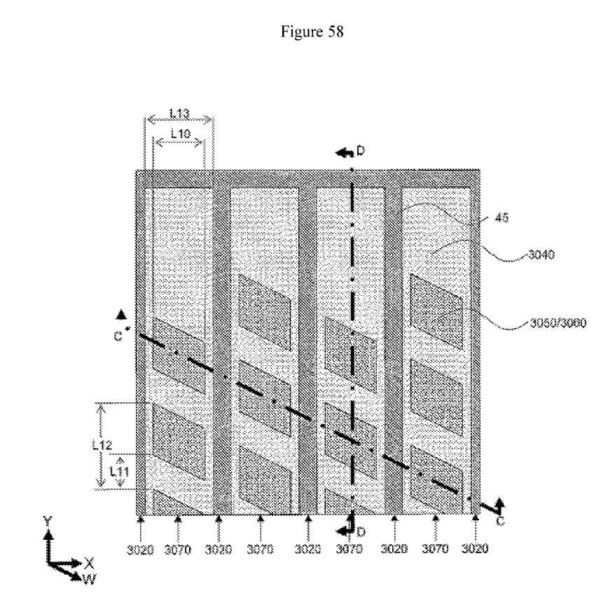

FIG. 57 is a cross-sectional view in which a cross-section along D-D in FIG. 55 is projected onto a vertical plane extending in the second direction Y.

The structure in the vicinity of the word contact plugs 4090 that are not illustrated in FIG. 56 will now be described with reference to FIG. 57.

First word contact holes 4020 are first disposed penetrating through the box layer 3010b from the reverse side of the memory semiconductor substrate 3010 to a depth that reaches the cell gate electrodes 3120, illustrated by the dashed line, in the element isolation regions 3040.

Second spacer films 4040 are then disposed on the sidewalls of the first word contact holes 4020. The first word contact holes 4020 are thus narrowed, forming second word contact holes 4060. The word contact plugs 4090 are then disposed in the second word contact holes 4060 in such a way as to be connected to the cell gate electrodes 3120.

Word contact pads 4110 are then disposed in such a way as to be connected to the word contact plugs 4090. The first interlayer insulating film 4120 is then disposed on the box layer 3010b in such a way as to embed the word contact pads 4110. Word wiring line contact plugs 4140 are then disposed in such a way as to penetrate through the first interlayer insulating film 4120 and connect to the word contact pads 4110.

Word wiring lines 4160 are then disposed on the first interlayer insulating film 4120 in such a way as to be connected to the word contact pads 4110. The second interlayer insulating film is then disposed on the first interlayer insulating film 4120 in such a way as to embed the word wiring lines 4160.

Word connection terminal contact plugs 4190 are then disposed in such a way as to penetrate through the second interlayer insulating film and connect to the word wiring lines 4160. The third interlayer insulating film 4220 is then disposed on the second interlayer insulating film.

Word connection terminals 4210 are then disposed in such a way as to penetrate through the third interlayer insulating film 4220 and connect to the word connection terminal contact plugs 4190.

With the abovementioned fifth mode of embodiment, ion implantation is required to counteract the sacrificial diffusion layers 107 in the word grooves, as illustrated in FIG. 37, but this process is not required in the seventh mode of embodiment of the present invention.

In the seventh mode of embodiment, by arranging that the STIs around the semiconductor pillars are produced with a convex shape, and by surrounding the periphery thereof with gate electrodes, the peripheries of the channel portions of the pillars are surrounded by the gates electrodes, from four directions, and an electric field is applied from the entire periphery. The ON/OFF characteristic of the transistor is thus improved compared with the abovementioned sixth mode of embodiment.

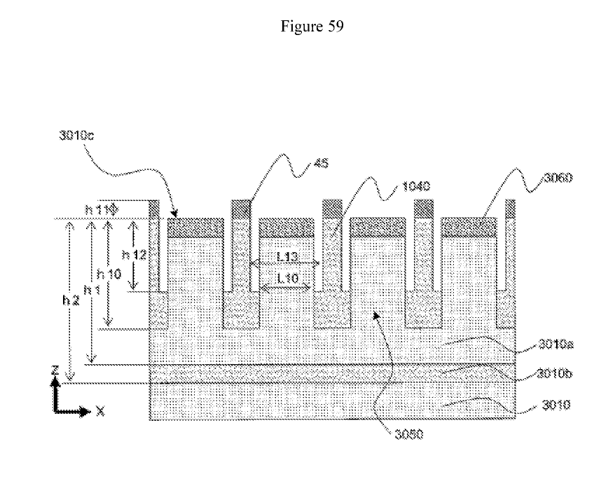

Reference is now made to FIG. 58 and FIG. 59. FIG. 58 is a plan view, and FIG. 59 is a cross-sectional view in which a cross-section along C-C in FIG. 58 is projected onto a vertical plane extending in the first direction X.

A silicon nitride film is deposited on the obverse surface of the memory semiconductor substrate 3010 to a thickness h6 (100 nm, for example), and lithography and dry etching are used to form a second masking silicon nitride film 45 in which a pattern having a width L13 (50 nm, for example) extending across the center of the active region 3050, and extending in the second direction Y, has been removed.

The element isolation regions 3040 are then etched, using the second masking silicon nitride film 45 as a mask, to a depth h7 from the obverse surface 3010c of the memory semiconductor substrate 3010, using dry etching in which the etching rate for a silicon dioxide film is greater than the etching rate for a silicon film/a silicon nitride film, to form word grooves 3070. The active regions 3050 thus remain in the word grooves 3070.

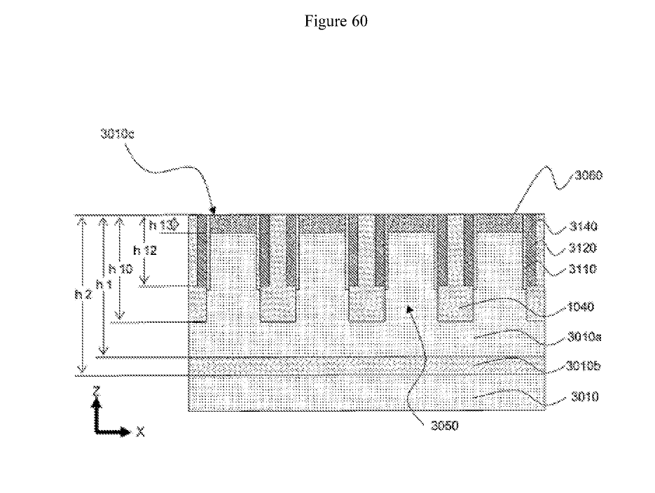

Reference is now made to FIG. 60. FIG. 60 is a cross-sectional view in which a cross-section along D-D in FIG. 58 is projected onto a vertical plane extending in the first direction X.

Cell gate insulating films 3110 are formed on the surfaces of the active regions 3050 by lamp annealing. Titanium nitride and tungsten are then deposited in such a way as to fill the word grooves 3070, and are then etched back to a depth h13 from the obverse surface 3010c of the memory cell semiconductor substrate 3010 to form the cell gate electrodes 3120. Because the active regions 3050 are surrounded by the cell gate electrodes 3120, the resulting construction is a construction known as a double-gate, and the ON/OFF characteristic of the transistor is improved compared with the abovementioned sixth mode of embodiment.

The seventh mode of embodiment of the present invention is subsequently completed by forming it in the same way as in the abovementioned sixth mode of embodiment. Finally, the memory semiconductor substrate is laminated to a second semiconductor chip.

Preferred modes of embodiment of the present invention have been described hereinabove, and the present invention has been described in terms of a chip having memory elements in a DRAM, and a CMOS chip having peripheral circuits, but various modifications may be made without deviating from the gist of the present invention, without limitation to the abovementioned modes of embodiment, and it goes without saying that, for example, a flash memory having gates which retain an electric charge, a variable-resistance type memory having variable-resistance elements (ReRAM: Resistance Random Access Memory), MRAM (Magnetic Random Access Memory) having magnetic-material elements or STT (Spin Transfer Torque)-RAM, serving as the non-volatile memory used for the chip having memory elements, are also included within the scope of the present invention.

This application is based upon Japanese Patent Application No. 2012-234556, filed on Oct. 24, 2012, Japanese Patent Application No. 2013-35026, filed on Feb. 25, 2013, and Japanese Patent Application No. 2013-183019, filed on Sep. 4, 2013, the entire disclosures of which are incorporated into this application by reference.

### REFERENCE SIGNS LIST

1 Semiconductor device
101 Memory semiconductor substrate
102 CMOS semiconductor substrate
103 First semiconductor pillar
104 Second semiconductor pillar
105 Source/drain diffusion layer
106 Bit contact diffusion layer
107 Sacrificial diffusion layer
150 Shot
151 Masking film
152 Pillar isolation groove
153 Pillar isolation insulating film
154 Word trench
155 Embedded insulating film
156 First gate insulating film
157 Second gate insulating film
158 First interlayer insulating film
159 Second interlayer insulating film
160 First protective insulating film
201 Semiconductor memory chip
202 Semiconductor CMOS chip
251 Capacitative contact hole
252 Capacitative contact plug
300 Circuit region
310 Memory cell region
311 Memory cell
312 Memory cell bank
313 Peripheral circuit bank
314 Bit line
314 A Bit line of subject bank
314 B Bit line of adjacent bank
315 Word line
320 Bit line connection terminal
330 Word line connection terminal
340 Sense amplifier circuit region
341 Sense amplifier transistor
350 Word line drive circuit region
351 Word line drive transistor
360 Peripheral circuit region
400 Silicon through-electrode
510 Memory chip connection terminal
520 CMOS chip connection terminal
701 Protective insulating film
711 Lower electrode
712 Capacitative insulating film
713 Capacitative electrode
610 Positioning protuberance (alignment protuberance)
620 Positioning hole (alignment recess)
630 IR mark
700 Contact
710 Capacitor
711 Lower electrode
712 Capacitative insulating film
713 Upper electrode
800 Wiring line
800 A Bit wiring line of subject bank
800 B Bit wiring line of adjacent bank
801 First wiring line
802 Second wiring line
803 Third wiring line
804 Fourth wiring line
801′ First wiring line (GND)
802′ Second wiring line (GND)
851 First via
852 Second via
853 Third via
854 Fourth via
800 A Bit wiring line of subject bank
800 B Bit wiring line of adjacent bank
900 Interlayer insulating film
911 to 914 Inter wiring-layer insulating film
910 Interlayer insulating film
920 Protective insulating film
930 Protective insulating film
950 Local wiring line layer
951 First wiring line layer
952 Second wiring line layer
953 Third wiring line layer
954 Connection terminal layer
960 Main word line
970 Global bit line
1010 Memory semiconductor substrate (SOI construction)
1010a Active region (p-type)
1010b Box layer
1010c Obverse surface
1030 Second element isolation groove
1040 Element isolation region (silicon dioxide)
1050 Active region
1060 Capacitative diffusion layer (n-type)
1070 Word groove
1070a Bottom
1070b First wall surface
1070c Second wall surface
1070d Third wall surface
1080 First semiconductor pillar
1090 Second semiconductor pillar
1100 Bit diffusion layer (n-type)
1120 First cell gate electrode (TiN)
1130 Second cell gate electrode (TiN)
1140 Cap insulating film (SiN)
1150 Capacitative element
1160 Protective insulating film
1170 Support substrate
2010 First bit contact groove
2030 First spacer film (SiO)
2040 Second spacer film (SiO)
2050 Second bit contact groove
2060 Second word contact hole
2070 Bit contact plug
2080 Word contact plug
2090 Bit line
2100 Word contact pad
2110 First interlayer insulating film
2120 Bit wiring line contact plug
2130 Word wiring line contact plug
2140 Bit wiring line
2150 Word wiring line
2160 Second interlayer insulating film
2170 Bit connection terminal contact plug
2180 Word connection terminal contact plug
2190 Bit connection terminal
2200 Word connection terminal
2210 Third interlayer insulating film
2220 Ground region
3010 Memory semiconductor substrate (SOI construction)
3010a Diffusion layer (p-type)
3010b Box layer
3010c Obverse surface
3020 First element isolation groove
3030 Second element isolation groove
3040 Element isolation region (silicon dioxide)
3050 Active region
3060 Capacitative diffusion layer (n-type)
3070 Word groove
3110 Cell gate insulating film (SiO)
3120 Cell gate electrode (TiN+W)
3140 Cap insulating film (SiN)
3150 Capacitative element
3160 Protective insulating film
3170 Support substrate
4010 First bit contact groove
4020 First word contact hole
4030 First spacer film (SiO)
4040 Second spacer film (SiO)
4050 Second bit contact groove
4060 Second word contact hole
4070 Bit diffusion layer (n-type)
4080 Bit contact plug
4090 Word contact plug
4100 Bit line
4110 Word contact pad
4120 First interlayer insulating film
4130 Bit wiring line contact plug
4140 Word wiring line contact plug
4150 Bit wiring line
4160 Word wiring line
4180 Bit connection terminal contact plug
4190 Word connection terminal contact plug
4200 Bit connection terminal
4210 Word connection terminal
4220 Third interlayer insulating film
4230 Ground region

1. A semiconductor device comprising:
a first semiconductor chip provided with a first function, including a memory element but not including a peripheral circuit;
first connection terminals provided in the first semiconductor chip;
a second semiconductor chip provided with a second function, including a peripheral circuit but not including a memory element; and
second connection terminals provided in the second semiconductor chip, wherein the first semiconductor chip and the second semiconductor chip are stacked on one another by causing the first connection terminals and the second connection terminals to come into contact with one another.

2. The semiconductor device according to claim 1, wherein the memory element in the first semiconductor chip is provided with a capacitor.

3.-5. (canceled)

6. The semiconductor device according to claim 1, wherein the memory element in the first semiconductor chip is provided with a non-volatile memory element.

7. The semiconductor device according to claim 6, wherein the non-volatile memory element includes any one of a flash memory, an ReRAM, an MRAM and an STT-RAM.

8. The semiconductor device according to claim 2, wherein the memory element in the first semiconductor chip is provided with a plurality of bit lines, a plurality of word lines, and a plurality of first connection terminals, and each of the plurality of bit lines and the plurality of word lines is connected respectively to one first connection terminal.

9. The semiconductor device according to claim 1, wherein the first semiconductor chip has transistors of only a first conductor type, and the second semiconductor chip has transistors of the first conductor type and a second conductor type.

10. The semiconductor device according to claim 1, wherein the first connection terminals and the second connection terminals are disposed in such a way that the positions of the centers of the connection terminals are equally spaced with respect to a first direction and a second direction which is perpendicular to the first direction.

11. The semiconductor device according to claim 1, wherein the first connection terminals and the second connection terminals are disposed in first rows that are disposed with a first pitch in the first direction, and in second rows that are disposed with the first pitch, offset in the first direction by half of the first pitch, and in that the first rows and the second rows are disposed alternately, with the first pitch, in the second direction which is perpendicular to the first direction.

12. The semiconductor device according to claim 1, wherein the second semiconductor chip has a through-electrode.

13. The semiconductor device according to claim 1, wherein the first connection terminal and the second connection terminal include copper.

14. (canceled)

15. The semiconductor device according to claim 1, wherein at least one semiconductor chip from the first semiconductor chip and the second semiconductor chip has an alignment protuberance, and at least the other semiconductor chip has an alignment recess, and the first semiconductor chip and the second semiconductor chip are stacked on one another with the alignment protuberance and the alignment recess mating with each other.

16.-19. (canceled)

20. The semiconductor device according to claim 1, wherein a bit line is disposed on the first semiconductor chip, and
a contact plug is electrically connected to the bit line and to the first connection terminal, and
the first connection terminal is disposed on a second main surface side of the semiconductor chip, the second main surface being on the opposite side to the first main surface.

21. The semiconductor device according to claim 20, wherein the bit line is disposed on the first main surface of the first semiconductor chip.

22. (canceled)

23. A semiconductor device comprising:
a first semiconductor chip having transistors of only a first conductor type;
first connection terminals provided in the first semiconductor chip;
a second semiconductor chip having transistors of the first conductor type and transistors of a second conductor type; and
second connection terminals provided in the second semiconductor chip, wherein the first semiconductor chip and the second semiconductor chip are stacked on one another by causing the first connection terminals and the second connection terminals to come into contact with one another.

24. The semiconductor device according to claim 23, wherein the first connection terminals and the second connection terminals are disposed in such a way that the positions of the centers of the connection terminals are equally spaced with respect to a first direction and a second direction which is perpendicular to the first direction.

25. The semiconductor device according to claim 23, wherein the first connection terminals and the second connection terminals are disposed in first rows that are disposed with a first pitch in the first direction, and in second rows that are disposed with the first pitch, offset in the first direction by half of the first pitch, and the first rows and the second rows are disposed alternately, with the first pitch, in the second direction which is perpendicular to the first direction.

26. The semiconductor device according to claim 23, wherein the second semiconductor chip has a through-electrode.

27. The semiconductor device according to claim 23, wherein the first connection terminal and the second connection terminal include copper.

28.-29. (canceled)

30. The semiconductor device according to claim 23, wherein the first semiconductor chip has only N-type transistors.

31. The semiconductor device according to claim 23, wherein at least one semiconductor chip from the first semiconductor chip and the second semiconductor chip has an alignment protuberance, and at least the other semiconductor chip has an alignment recess, and the first semiconductor chip and the second semiconductor chip are stacked on one another with the alignment protuberance and the alignment recess mating with each other.

32.-42. (canceled)
